(19) United States
(12) Patent Application Publication
(10) Pub. No.: US 2025/0293155 A1
(43) Pub. Date: Sep. 18, 2025

(54) BACKEND TRANSISTOR FORMATION TECHNIQUES INCLUDING SEEDED EPITAXIAL GROWTH

(71) Applicant: Intel Corporation, Santa Clara, CA (US)

(72) Inventors: Abhishek A. Sharma, Portland, OR (US); Sagar Suthram, Portland, OR (US); Wilfred Gomes, Portland, OR (US); Tahir Ghani, Portland, OR (US); Anand S. Murthy, Portland, OR (US)

(73) Assignee: Intel Corporation, Santa Clara, CA (US)

(21) Appl. No.: 18/603,315

(22) Filed: Mar. 13, 2024

(51) Int. Cl. H01L 23/528; H01L 21/8238; H01L 27/092; H01L 29/04; H01L 29/06; H01L 29/66; H01L 29/778; H01L 29/78

(52) U.S. Cl. CPC H01L 23/5283; H10D 30/024; H10D 30/47; H10D 30/6211; H10D 62/118; H10D 62/40; H10D 84/0167; H10D 84/0193; H10D 84/038; H10D 84/853

(57) ABSTRACT

Disclosed herein are integrated circuit (IC) structures with backend transistors, including backend transistors fabricated using seeded epitaxial growth techniques. In one example, an IC structure includes a semiconductor structure (e.g., a seed structure) over an interconnect layer, where the semiconductor structure includes a first semiconductor material with a first crystal lattice orientation, and a second semiconductor material over the semiconductor structure, where the second semiconductor material has a second crystal lattice orientation that is substantially the same as the first crystal lattice orientation, and where a portion of the second semiconductor material is a channel region of a backend transistor. In one example, the IC structure may also include a third semiconductor material (e.g., a textured template material) between the seed structure and the second semiconductor material.

### BACKGROUND

For the past several decades, the scaling of features in integrated circuits (ICs) has been a driving force behind an ever-growing semiconductor industry. Scaling to smaller and smaller features enables increased densities of functional units on the limited real estate of semiconductor chips. For example, shrinking transistor size allows for the incorporation of an increased number of memory or logic devices on a chip, lending to the fabrication of products with increased capacity. The drive for the ever-increasing capacity, however, is not without issue. The necessity to optimize fabrication and performance of each component is becoming increasingly significant.

### BRIEF DESCRIPTION OF THE DRAWINGS

Embodiments will be readily understood by the following detailed description in conjunction with the accompanying drawings. To facilitate this description, like reference numerals designate like structural elements. Embodiments are illustrated by way of example, and not by way of limitation, in the figures of the accompanying drawings.

FIG. 1 is a cross-sectional side view of a transistor gate-channel arrangement including a transistor gate stack, in accordance with various embodiments.

FIGS. 2-5 are cross-sectional side views of example single-gate transistors including a transistor gate stack, in accordance with various embodiments.

FIGS. 6-7 are cross-sectional side views of example double-gate transistors including a transistor gate stack, in accordance with various embodiments.

FIGS. 8A and 8B are perspective and cross-sectional side views, respectively, of an example tri-gate transistor including a transistor gate stack, in accordance with various embodiments.

FIGS. 9A and 9B are perspective and cross-sectional side views, respectively, of an example all-around gate transistor including a transistor gate stack, in accordance with various embodiments.

FIGS. 10A-10D illustrate example IC structures in which backend transistors may be implemented.

FIG. 11 is a flow diagram of an example method for fabricating an IC device with backend transistors, including seeded epitaxial grown techniques, in accordance with some embodiments.

FIGS. 12A-12B, 13A-13B, 14A-14B, and 15A-15B are cross-sectional views at various stages in the fabrication of example IC structures according to the method of FIG. 11, in accordance with some embodiments.

FIG. 16A-16B is a cross-sectional view of another example IC structure during fabrication of the IC structure according to the method of FIG. 11, in accordance with some embodiments.

FIG. 17 is a flow diagram of an example method for fabricating an IC device with backend transistors, in accordance with some embodiments.

FIGS. 18A-18B, 19A-19B, and 20A-20B are cross-sectional views at various stages in the fabrication of example IC structures according to the method of FIG. 17, in accordance with some embodiments.

FIG. 21 is a top view of a wafer and dies that may include any of the IC structures disclosed herein, in accordance with any of the embodiments disclosed herein.

FIG. 22 is a side, cross-sectional view of an IC package that may include any of the IC structures disclosed herein, in accordance with various embodiments.

FIG. 23 is a side, cross-sectional view of an IC device assembly that may include any of the IC structures disclosed herein, in accordance with any of the embodiments disclosed herein.

FIG. 24 is a block diagram of an example electrical device that may include any of the IC structures disclosed herein, in accordance with any of the embodiments disclosed herein.

### DETAILED DESCRIPTION

Disclosed herein are integrated circuit (IC) structures with backend transistors, including backend transistors fabricated using seeded epitaxial growth techniques.

As the drive for increased device density on semiconductor chips continues, techniques involving layer transfer have emerged for fabricating IC devices with transistors in both the frontend and backend layers. Layer transfer may involve separating a thin sheet or film of semiconductor material from one substrate and transferring the thin film to another substrate. Although layer transfer techniques can enable providing high quality semiconductor layers over a processed wafer, layer transfer techniques can be prohibitively expense and susceptible to defects. For example, the surfaces of both the thin film and the surface of the substrate onto which the thin film is to be transferred typically have defects, which can result in a defective interface between the transferred thin film and the underlying substrate.

In contrast, using seeded epitaxial growth techniques may enable forming backend transistors without the high cost and risk of defects associated with layer transfer. In one example, a seed structure in and/or over an interconnect layer of an IC structure is used to deposit a layer of a semiconductor material having the substantially same crystal orientation as the seed structure. In one example, the layer of the semiconductor material may be used as a textured or structured template to epitaxially grow a further semiconductor material that may then form the basis of a channel region of a backend transistor, or the semiconductor material may be the channel material. In one example, a resulting IC structure may include a semiconductor structure (e.g., a seed structure) over an interconnect layer, where the semiconductor structure includes a first semiconductor material with a first crystal lattice orientation, and a second semiconductor material (e.g., the semiconductor material from which transistor channel regions are formed) over the semiconductor structure, where the second semiconductor material has a second crystal lattice orientation that is substantially the same as the first crystal lattice orientation. In one example, the IC structure may also include a third semiconductor material (e.g., a textured template material) between the seed structure and the second semiconductor material. Accordingly, a monolithic three-dimensional IC structure (e.g., an IC structure with devices in both the frontend and backend) may be formed without layer transfer techniques, which may enable lower cost and/or lower defect three-dimensional IC structures.

IC structures with backend transistors fabricated using seeded epitaxial growth as described herein may be implemented in one or more components associated with an IC or/and between various such components. In various embodiments, components associated with an IC include, for example, transistors, diodes, power sources, resistors, capacitors, inductors, sensors, transceivers, receivers, antennas, etc. Components associated with an IC may include those that are mounted on an IC or those connected to an IC. The IC may be either analog or digital and may be used in a number of applications, such as microprocessors, optoelectronics, logic blocks, audio amplifiers, etc., depending on the components associated with the IC. In some embodiments, IC structures as described herein may be included in a radio frequency IC (RFIC), which may, e.g., be included in any component associated with an IC of a radio frequency (RF) receiver, an RF transmitter, or an RF transceiver, e.g., as used in telecommunications within base stations (BS) or user equipment (UE). Such components may include, but are not limited to, power amplifiers, low-noise amplifiers, RF filters (including arrays of RF filters, or RF filter banks), switches, upconverters, downconverters, and duplexers. In some embodiments, IC structures as described herein may be included in memory devices or circuits. In some embodiments, IC structures as described herein may be employed as part of a chipset for executing one or more related functions in a computer.

For purposes of explanation, specific numbers, materials and configurations are set forth in order to provide a thorough understanding of the illustrative implementations. However, it will be apparent to one skilled in the art that the present disclosure may be practiced without the specific details or/and that the present disclosure may be practiced with only some of the described aspects. In other instances, well-known features are omitted or simplified in order not to obscure the illustrative implementations. The terms “substantially,” “close,” “approximately,” “near,” and “about,” generally refer to being within +/−10% of a target value, e.g., within +/−5% of a target value, based on the context of a particular value as described herein or as known in the art. Similarly, terms indicating orientation of various elements, e.g., “coplanar,” “perpendicular,” “orthogonal,” “parallel,” or any other angle between the elements, generally refer to being within +/−10% of a target value, e.g., within +/−5% of a target value, based on the context of a particular value as described herein or as known in the art.

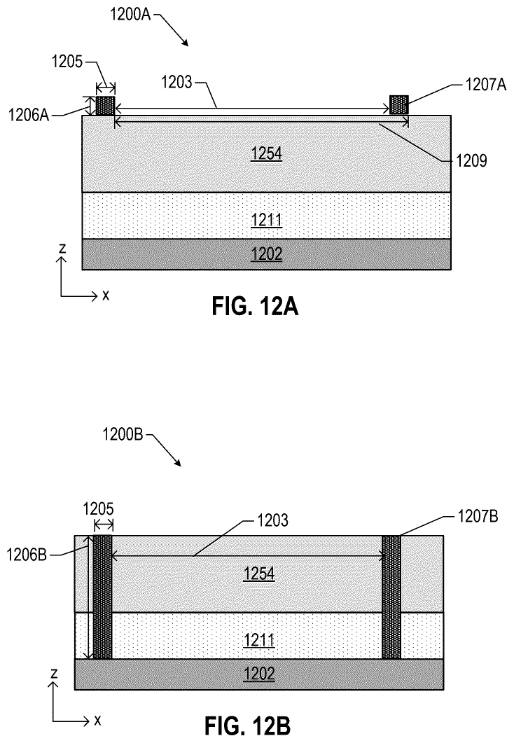

In the following description, references are made to the accompanying drawings that form a part hereof, and in which is shown, by way of illustration, embodiments that may be practiced. It is to be understood that other embodiments may be utilized, and structural or logical changes may be made without departing from the scope of the present disclosure. Therefore, the following detailed description is not to be taken in a limiting sense. For convenience, if a collection of drawings designated with different letters are present, e.g., FIGS. 12A-12B, such a collection may be referred to herein without the letters, e.g., as “FIG. 12.”

In the drawings, while some schematic illustrations of example structures of various devices and assemblies described herein may be shown with precise right angles and straight lines, this is simply for ease of illustration, and embodiments of these assemblies may be curved, rounded, or otherwise irregularly shaped as dictated by, and sometimes inevitable due to, the fabricating processes used to fabricate semiconductor device assemblies. Therefore, it is to be understood that such schematic illustrations may not reflect real-life process limitations which may cause the features to not look so “ideal” when any of the structures described herein are examined using e.g., scanning electron microscopy (SEM) images or transmission electron microscope (TEM) images. In such images of real structures, possible processing defects could also be visible, e.g., not-perfectly straight edges of materials, tapered vias or other openings, inadvertent rounding of corners or variations in thicknesses of different material layers, occasional screw, edge, or combination dislocations within the crystalline region, and/or occasional dislocation defects of single atoms or clusters of atoms. There may be other defects not listed here but that are common within the field of device fabrication. Inspection of layout and mask data and reverse engineering of parts of a device to reconstruct the circuit using e.g., optical microscopy, TEM, or SEM, and/or inspection of a cross-section of a device to detect the shape and the location of various device elements described herein using, e.g., Physical Failure Analysis (PFA) would allow determination of presence of IC structures with backend transistors fabricated using seeded epitaxial growth techniques as described herein.

Various operations may be described as multiple discrete actions or operations in turn, in a manner that is most helpful in understanding the claimed subject matter. However, the order of description should not be construed as to imply that these operations are necessarily order dependent. These operations may not be performed in the order of presentation. Operations described may be performed in a different order from the described embodiment. Various additional operations may be performed, and/or described operations may be omitted in additional embodiments.

For the purposes of the present disclosure, the phrase “A and/or B” means (A), (B), or (A and B). For the purposes of the present disclosure, the phrase “A, B, and/or C” means (A), (B), (C), (A and B), (A and C), (B and C), or (A, B, and C). The term “between,” when used with reference to measurement ranges, is inclusive of the ends of the measurement ranges.

The description uses the phrases “in an embodiment” or “in embodiments,” which may each refer to one or more of the same or different embodiments. The terms “comprising,” “including,” “having,” and the like, as used with respect to embodiments of the present disclosure, are synonymous. The disclosure may use perspective-based descriptions such as “above,” “below,” “top,” “bottom,” and “side”; such descriptions are used to facilitate the discussion and are not intended to restrict the application of disclosed embodiments. The accompanying drawings are not necessarily drawn to scale. Unless otherwise specified, the use of the ordinal adjectives “first,” “second,” and “third,” etc., to describe a common object, merely indicate that different instances of like objects are being referred to and are not intended to imply that the objects so described must be in a given sequence, either temporally, spatially, in ranking or in any other manner. Although some materials may be described in singular form, such materials may include a plurality of materials, e.g., a semiconductor material may include two or more different semiconductor materials.

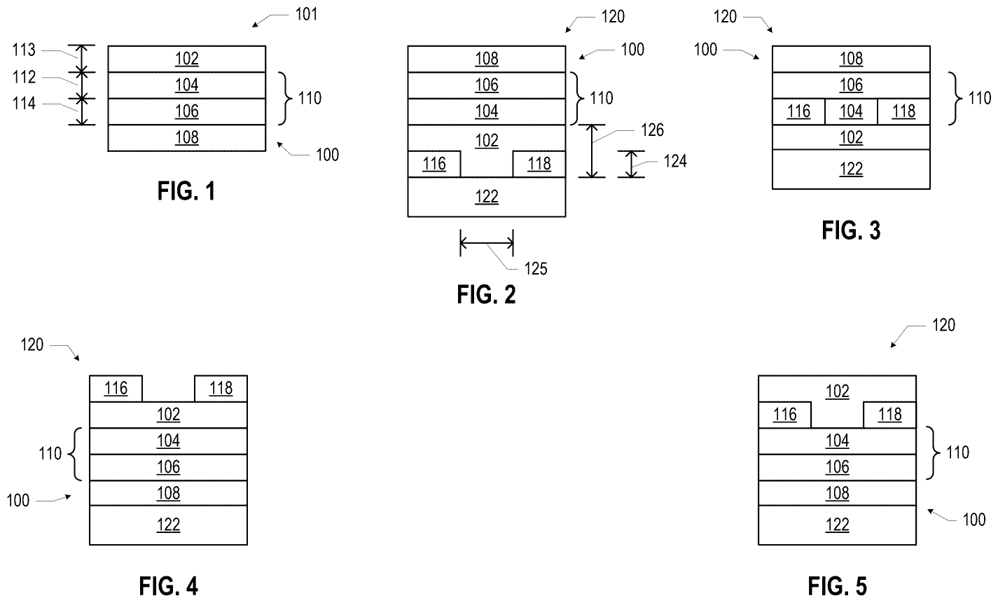

IC structures including backend transistors may include transistors of any architecture, such as any non-planar or planar architecture. Non-planar transistors such as double-gate transistors, tri-gate transistors, FinFETs, and nanowire/nanoribbon/nanosheet transistors refer to transistors having a non-planar architecture. In comparison to a planar architecture where the transistor channel has only one confinement surface, a non-planar architecture is any type of architecture where the transistor channel has more than one confinement surface. A confinement surface refers to a particular orientation of the channel surface that is confined by the gate field. Non-planar transistors potentially improve performance relative to transistors having a planar architecture, such as single-gate transistors. FIGS. 1-9B illustrate examples of IC structures including different transistor architectures that may be implemented as backend transistors using techniques described herein.

FIG. 1 is a cross-sectional side view of a transistor gate-channel arrangement 101 including a channel material 102 and a transistor gate stack 100 (also referred to as a “gate stack 100” herein), in accordance with various embodiments. FIGS. 2-9B illustrate transistors of different architectures in which the gate stack 100 of FIG. 1 may be implemented. N-type and P-type transistors of IC structures with backend transistors as described herein may be transistors of any of the architectures described with reference to FIGS. 2-9B.

Turning to the details of FIG. 1, as shown, the transistor gate stack 100 may include a gate electrode material 108, and a gate dielectric stack 110 disposed between the gate electrode material 108 and the channel material 102.

The channel material 102 may be composed of semiconductor material systems including, for example, N-type or P-type materials systems. In some embodiments, the channel material 102 may include a high mobility oxide semiconductor material, such as tin oxide, antimony oxide, indium oxide, indium tin oxide, titanium oxide, zinc oxide, indium zinc oxide, gallium oxide, titanium oxynitride, ruthenium oxide, or tungsten oxide. In some embodiments, the channel material 102 may include a combination of semiconductor materials. In some embodiments, the channel material 102 may include a monocrystalline semiconductor, such as silicon (Si) or germanium (Ge). In some embodiments, the channel material 102 may include a compound semiconductor with a first sub-lattice of at least one element from group III of the periodic table (e.g., Al, Ga, In), and a second sub-lattice of at least one element of group V of the periodic table (e.g., P, As, Sb).

For some example N-type transistor embodiments (e.g., for the embodiments where a transistor 120 of any of FIGS. 2-9 is an N-type metal oxide semiconductor (NMOS) transistor), the channel material 102 may include a III-V material having a relatively high electron mobility, such as, but not limited to InGaAs, InP, InSb, and InAs. For some such embodiments, the channel material 102 may be a ternary III-V alloy, such as InGaAs, GaAsSb, InAsP, or InPSb. For some InₓGa₁₋ₓAs fin embodiments, In content (x) may be between 0.6 and 0.9, and may advantageously be at least 0.7 (e.g., In_{0.7}Ga_{0.3}As). For some example P-type transistor embodiments (e.g., for the embodiments where a transistor 120 of any of FIGS. 2-9 is a P-type metal oxide semiconductor (PMOS) transistor), the channel material 102 may advantageously be a group IV material having a high hole mobility, such as, but not limited to Ge or a Ge-rich SiGe alloy. For some example embodiments, the channel material 102 may have a Ge content between 0.6 and 0.9, and advantageously may be at least 0.7.

In some embodiments, the channel material 102 may be a thin-film material, such as a high mobility oxide semiconductor material, such as tin oxide, antimony oxide, indium oxide, indium tin oxide, titanium oxide, zinc oxide, indium zinc oxide, indium gallium zinc oxide (IGZO), gallium oxide, titanium oxynitride, ruthenium oxide, or tungsten oxide. In general, if a transistor is a thin-film transistor (TFT), the channel material 102 may include one or more of tin oxide, cobalt oxide, copper oxide, antimony oxide, ruthenium oxide, tungsten oxide, zinc oxide, gallium oxide, titanium oxide, indium oxide, titanium oxynitride, indium tin oxide, indium zinc oxide, nickel oxide, niobium oxide, copper peroxide, IGZO, indium telluride, molybdenite, molybdenum diselenide, tungsten diselenide, tungsten disulfide, N- or P-type amorphous or polycrystalline silicon, germanium, indium gallium arsenide, silicon germanium, gallium nitride, aluminum gallium nitride, indium phosphite, and black phosphorus, each of which may possibly be doped with one or more of gallium, indium, aluminum, fluorine, boron, phosphorus, arsenic, nitrogen, tantalum, tungsten, and magnesium, etc. The channel material 102 may have a thickness 113. In some embodiments, the thickness 113 may be between about 5 and 75 nanometers, including all values and ranges therein, e.g., between about 5 and 30 nanometers.

The gate electrode material 108 may include at least one P-type work function metal or N-type work function metal, depending on whether the transistor gate stack 100 is to be included in a P-type transistor or an N-type transistor. For a P-type transistor, metals that may be used for the gate electrode material 108 may include, but are not limited to, ruthenium, palladium, platinum, cobalt, nickel, and conductive metal oxides (e.g., ruthenium oxide). For an N-type transistor, metals that may be used for the gate electrode material 108 include, but are not limited to, hafnium, zirconium, titanium, tantalum, aluminum, alloys of these metals, and carbides of these metals (e.g., hafnium carbide, zirconium carbide, titanium carbide, tantalum carbide, and aluminum carbide). In some embodiments, the gate electrode material 108 may include a stack of two or more metal layers, where one or more metal layers are work function metal layers and at least one metal layer is a fill metal layer. Further metal layers may be included for other purposes, such as to act as a barrier layer.

The gate dielectric stack 110 may include one or more insulator materials. As shown in FIG. 1, the gate dielectric stack 110 includes a high-k dielectric 106 and an insulator material 104, however, in other examples, the transistor gate stack 100 includes a single insulator material between the gate electrode material 108 and the channel material 102. For example, the transistor gate stack 100 may include only a high-k dielectric 106 between the gate electrode material 108 and the channel material 102. The high-k dielectric 106 may include elements such as hafnium, silicon, oxygen, titanium, tantalum, lanthanum, aluminum, zirconium, barium, strontium, yttrium, lead, scandium, niobium, and zinc. Examples of high-k materials that may be used in the high-k dielectric 106 may include, but are not limited to, hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, tantalum oxide, tantalum silicon oxide, lead scandium tantalum oxide, and lead zinc niobate. In some embodiments, an annealing process may be carried out on the high-k dielectric 106 during manufacture of the gate stack 100 to improve the quality of the high-k dielectric 106. The high-k dielectric 106 may have a thickness 114. In some embodiments, the thickness 114 may be between 0.5 nanometers and 3 nanometers (e.g., between 1 and 3 nanometers, or between 1 and 2 nanometers).

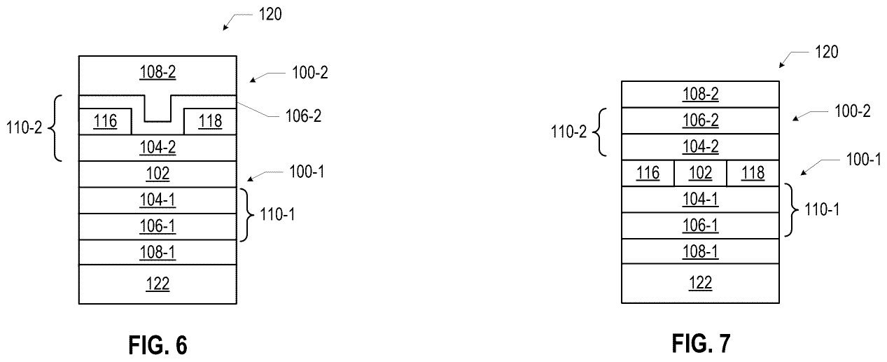

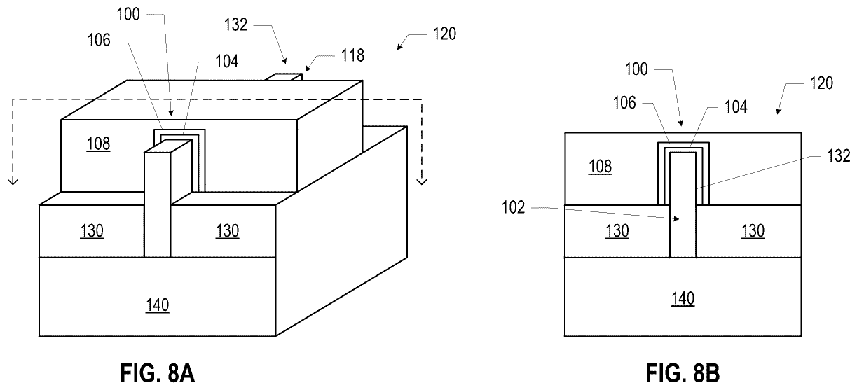

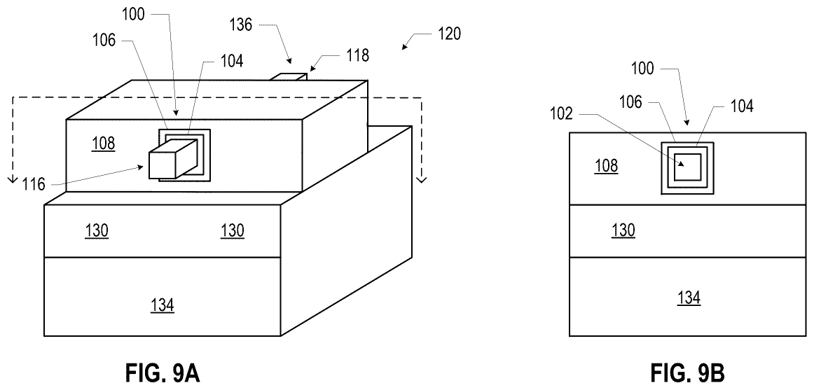

FIGS. 2-9 illustrate examples of transistors that may be implemented as backend transistors fabricated using seeded epitaxial growth techniques. FIGS. 2-5 are cross-sectional side views of example single-gate transistors 120, FIGS. 6-7 are cross-sectional side views of example double-gate transistors 120, FIGS. 8A and 8B are perspective and cross-sectional side views, respectively, of an example tri-gate transistor 120, and FIGS. 9A and 9B are perspective and cross-sectional side views, respectively, of an example all-around gate transistor 120, any of which may be implemented as backend transistors in accordance with various embodiments. The transistors 120 illustrated in FIGS. 2-9 do not represent an exhaustive set of transistor structures that may be implemented as backend transistors as described herein, but that may provide examples of such structures. Note that FIGS. 2-9 are intended to show relative arrangements of the components therein, and that transistors 120 may include other components that are not illustrated (e.g., electrical contacts to the source region 116 and the drain region 118 to transport current in and out of the transistors 120). Any of the components of the transistors 120 discussed below with reference to FIGS. 2-9 may take the form of any of the embodiments of those components discussed above with reference to FIG. 1. Additionally, although various components of the transistors 120 are illustrated in FIGS. 2-9 as being planar rectangles or formed of rectangular solids, this is simply for ease of illustration, and embodiments of these transistors 120 may be curved, rounded, or otherwise irregularly shaped as dictated by the manufacturing processes used to fabricate the transistors 120.

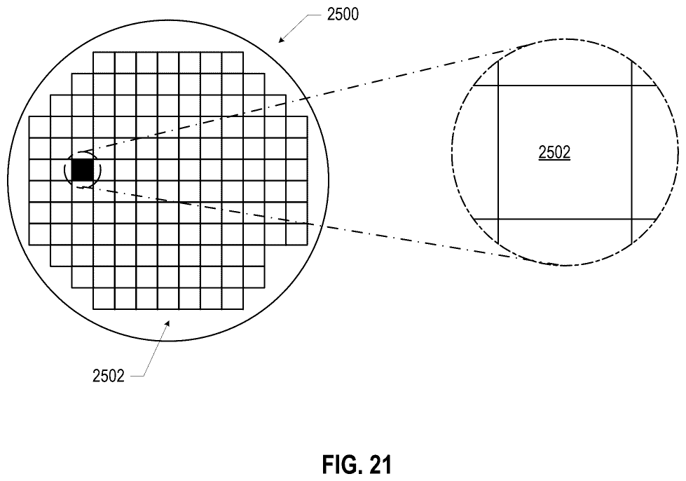

FIG. 2 depicts a transistor 120 having a single “top” gate provided by the gate electrode material 108, and which may be implemented as a backend transistor in accordance with examples herein. The gate dielectric stack 110 may be disposed between the gate electrode material 108 and the channel material 102. The gate dielectric stack 110 may border the channel material 102; in particular, the insulator material 104 may contact the channel material 102 without any intervening material in some embodiments. In the embodiment of FIG. 2, the gate stack 100 is shown as disposed on a support 122. The support 122 may be any structure, e.g., a substrate, a die, a wafer, or a chip, on which the gate stack 100, or other elements of the transistor 120, is disposed. The support 122 may, e.g., be the wafer 2500 of FIG. 21, discussed below, and may be, or be included in, a die, e.g., the singulated die 2502 of FIG. 21, discussed below. In some embodiments, the support 122 may be a semiconductor substrate composed of semiconductor material systems including, for example, N-type or P-type materials systems. In one implementation, the semiconductor substrate may be a crystalline substrate formed using a bulk silicon or a silicon-on-insulator (SOI) substructure. In other implementations, the semiconductor substrate may be formed using alternate materials, which may or may not be combined with silicon, that include, but are not limited to, germanium, silicon germanium, indium antimonide, lead telluride, indium arsenide, indium phosphide, gallium arsenide, aluminum gallium arsenide, aluminum arsenide, indium aluminum arsenide, aluminum indium antimonide, indium gallium arsenide, gallium nitride, indium gallium nitride, aluminum indium nitride or gallium antimonide, or other combinations of group III-V materials (i.e., materials from groups III and V of the periodic system of elements), group II-VI (i.e., materials from groups II and IV of the periodic system of elements), or group IV materials (i.e., materials from group IV of the periodic system of elements). In some embodiments, the substrate may be non-crystalline. In some embodiments, the support 122 may be a printed circuit board (PCB) substrate, a package substrate, an interposer, a wafer, or a die. In some embodiments, the support 122 may include an insulating layer, such as an oxide isolation layer. For example, in the embodiments of FIGS. 2 and 3, the support 122 may include a semiconductor material and an interface layer dielectric (ILD) disposed between the semiconductor material and the source region 116, the channel material 102, and the drain region 118, to electrically isolate the semiconductor material of the support 122 from the source region 116, the channel material 102, and the drain region 118 (and thereby mitigate the likelihood that a conductive pathway will form between the source region 116 and the drain region 118 through the support 122). Examples of ILDs that may be included in a support 122 in some embodiments may include silicon oxide, silicon nitride, aluminum oxide, and/or silicon oxynitride. Any suitable ones of the embodiments of the support 122 described with reference to FIG. 2 may be used for the substrates of others of the transistors disclosed herein. For IC structures that include backend transistors, the support 122 may include front end of line (FEOL) layer(s) and/or back end of line (BEOL) layer(s) of the IC device, as discussed in more detail below.

As noted above, the transistor 120 may include a source region 116 and a drain region 118 disposed on the support 122, with the channel material 102 disposed between the source region 116 and the drain region 118 so that at least some of the channel material 102 is coplanar with at least some of the source region 116 and the drain region 118. The source region 116 and the drain region 118 may have a thickness 124, and the channel material 102 may have a thickness 126. The thickness 126 may take the form of any of the embodiments of the thickness 113 discussed above with reference to FIG. 1. In some embodiments, the thickness 124 may be less than the thickness 126 (as illustrated in FIG. 2, with the source region 116 and the drain region 118 each disposed between some of the channel material 102 and the support 122), while in other embodiments, the thickness 124 may be equal to the thickness 126. In some embodiments, the channel material 102, the insulator material 104, the high-k dielectric 106, and/or the gate electrode material 108 may conform around the source region 116 and/or the drain region 118. The source region 116 and the drain region 118 may be spaced apart by a distance 125 that is the gate length of the transistor 120. In some embodiments, the gate length may be between about 5 and 40 nanometers, including all values and ranges therein (e.g., between about 22 and 35 nanometers, or between about 20 and 30 nanometers).

The source region 116 and the drain region 118 may be highly doped semiconductors, e.g., with dopant concentrations of about 10²¹ dopants per cubic centimeter (cm⁻³), in order to advantageously form Ohmic contacts with the respective source or drain contacts (not shown in FIG. 1), although these regions may also have lower dopant concentrations and may form Schottky contacts in some implementations. Irrespective of the exact doping levels, the source region 116 and the drain region 118 of a transistor are the regions having dopant concentration higher than in other regions, e.g., higher than a dopant concentration in the transistor channel (i.e., in a channel material extending between the source region 116 and the drain region 118), and, therefore, may be referred to as “highly doped” (HD) regions. Even when doped to realize threshold voltage tuning as described herein, the channel portions of transistors typically include semiconductor materials with doping concentrations significantly smaller than those of the source region 116 and the drain region 118.

The source region 116 and the drain region 118 of the transistor 120 may generally be formed using either an implantation/diffusion process or an etching/deposition process. In the former process, dopants such as boron, aluminum, antimony, phosphorous, or arsenic may be ion-implanted into the channel material 102 to form the source and drain regions. An annealing process that activates the dopants and causes them to diffuse further into the channel material 102 may follow the ion implantation process. In the latter process, portions of the channel material 102 may first be etched to form recesses at the locations of the future source region 116 and drain region 118. An epitaxial deposition process may then be carried out to fill the recesses with material that is used to fabricate the source region 116 and the drain region 118. In some implementations, the source region 116 and the drain region 118 may be fabricated using a silicon alloy such as silicon germanium or silicon carbide. In some implementations, the epitaxially deposited silicon alloy may be doped in situ with dopants such as boron, arsenic, or phosphorous. In further embodiments, the source region 116 and the drain region 118 may be formed using one or more alternate semiconductor materials such as germanium or a group III-V material or alloy. And in further embodiments, one or more layers of metal and/or metal alloys may be used to form the source region 116 and the drain region 118. Because, as is common in the field of field effect transistors (FETs), designations of source and drain are often interchangeable, the source region 116 and the drain region 118 of the transistor 120 may simply be referred to herein as a first source or drain (S/D) region and a second S/D region.

FIG. 3 depicts a transistor 120 including a single “top” gate provided by the gate electrode material 108, and which may be implemented as a backend transistor in accordance with examples herein. The gate dielectric stack 110 may be disposed between the gate electrode material 108 and the channel material 102. In the embodiment of FIG. 3, the gate stack 100 is shown as disposed on a support 122. The transistor 120 may include a source region 116 and a drain region 118 disposed on the support 122, with the insulator material 104 disposed between the source region 116 and the drain region 118 so that at least some of the insulator material 104 is coplanar with at least some of the source region 116 and the drain region 118. As discussed above, in some embodiments, the support 122 of FIG. 3 may include a semiconductor material and ILD disposed between the semiconductor material and the source region 116, the channel material 102, and the drain region 118, to electrically isolate the semiconductor material of the support 122 from the source region 116, the channel material 102, and the drain region 118. In some embodiments, the insulator material 104, the high-k dielectric 106, and/or the gate electrode material 108 may conform around the source region 116 and/or the drain region 118.

FIG. 4 depicts a transistor 120 having a single “bottom” gate provided by the gate electrode material 108, and which may be implemented as a backend transistor in accordance with examples herein. The gate dielectric stack 110 may be disposed between the gate electrode material 108 and the channel material 102. In the embodiment of FIG. 4, the gate stack 100 is shown as disposed on a support 122 in an orientation “upside down” to the one illustrated in FIG. 2; that is, the gate electrode material 108 may be disposed between the support 122 and the channel material 102. The transistor 120 may include a source region 116 and a drain region 118 disposed on the channel material 102 such that the source region 116 and the drain region 118 are not coplanar with the channel material 102.

FIG. 5 depicts a transistor 120 having a single “bottom” gate provided by the gate electrode material 108, which may be implemented as a backend transistor in accordance with examples herein. The gate dielectric stack 110 may be disposed between the gate electrode material 108 and the channel material 102. In the embodiment of FIG. 5, the gate stack 100 is shown as disposed on a support 122 in an orientation “upside down” to the one illustrated in FIG. 2; that is, the gate electrode material 108 may be disposed between the support 122 and the channel material 102. The transistor 120 may include a source region 116 and a drain region 118 disposed on the channel material 102 such that at least some of the source region 116 and at least some of the drain region 118 are coplanar with at least some of the channel material 102. In some embodiments, the source region 116 and the drain region 118 may each be disposed between some of the channel material 102 and the support 122, as illustrated in FIG. 5, while in other embodiments, the channel material 102 may not extend “above” the source region 116 or the drain region 118. In some embodiments, the channel material 102 may conform around the source region 116 and/or the drain region 118.

FIG. 6 depicts a double-gate transistor 120 including two transistor gate stacks 100-1 and 100-2 and having “bottom” and “top” gates provided by the gate electrode material 108-1/gate dielectric stack 110-1 and the gate electrode material 108-2/gate dielectric stack 110-2, respectively. The gate dielectric stacks 110-1 and 110-2 may include high-k dielectrics 106-1 and 106-2, and insulator materials 104-1 and 104-2, respectively. Each gate dielectric stack 110 may be disposed between the corresponding gate electrode material 108 and the channel material 102. The transistor 120 may include a source region 116 and a drain region 118 disposed proximate to the channel material 102. In the embodiment illustrated in FIG. 6, the source region 116 and the drain region 118 are disposed on the insulator material 104-2, and the high-k dielectric 106-2 is disposed conformably around the source region 116, the insulator material 104-2, and the drain region 118. The gate electrode material 108-2 is disposed on the high-k dielectric 106-2. In the embodiment of FIG. 6, at least some of the source region 116 and at least some of the drain region 118 are coplanar with at least some of the high-k dielectric 106-2.

FIG. 7 depicts a double-gate transistor 120 including two transistor gate stacks 100-1 and 100-2 and having “bottom” and “top” gates provided by the gate electrode material 108-1/gate dielectric stack 110-1 and the gate electrode material 108-2/gate dielectric stack 110-2, respectively. Each gate dielectric stack 110 may include a high-k dielectric 106. The transistor 120 may include a source region 116 and a drain region 118 disposed proximate to the channel material 102. In the embodiment illustrated in FIG. 7, the source region 116 and the drain region 118 are coplanar with the channel material 102, and disposed between the high-k dielectrics 106-1 and 106-2. The relative arrangement of the source region 116, the drain region 118, and the channel material 102 may take the form of any of the embodiments discussed above with reference to FIG. 2.

FIGS. 8A and 8B are perspective and cross-sectional side views, respectively, of an example tri-gate transistor 120 including a transistor gate stack 100, in accordance with various embodiments. The transistor 120 of FIGS. 8A and 8B may include a channel material 102, and a gate stack 100 including a gate electrode material 108 and a high-k dielectric 106. In the tri-gate transistor 120 illustrated in FIGS. 8A and 8B, a fin 132 formed of a semiconductor material may extend from a base 140 of the semiconductor material. An oxide material 130 may be disposed on either side of the fin 132. In some embodiments, the oxide material 130 may include any of the materials discussed herein with reference to the high-k dielectric 106.

The gate stack 100 may wrap around the fin 132 as shown, with the channel material 102 corresponding to the portion of the fin 132 wrapped by the gate stack 100. In particular, the insulator material 104 may wrap around the channel material 102 of the fin 132, the high-k dielectric 106 may wrap around the insulator material 104, and the gate electrode material 108 may wrap around the high-k dielectric 106. The fin 132 may include a source region 116 and a drain region 118 on either side of the gate stack 100, as shown. The composition of the channel material 102, the source region 116, and a drain region 118 may take the form of any of the embodiments disclosed herein, or known in the art. Although the fin 132 illustrated in FIGS. 8A and 8B is shown as having a rectangular cross section, the fin 132 may instead have a cross section that is rounded or sloped at the “top” of the fin 132, and the gate stack 100 may conform to this rounded or sloped fin 132. In use, the tri-gate transistor 120 may form conducting channels on three “sides” of the fin 132, potentially improving performance relative to single-gate transistors (which may form conducting channels on one “side” of the channel material 102) and double-gate transistors (which may form conducting channels on two “sides” of the channel material 102).

FIGS. 9A and 9B are perspective and cross-sectional side views, respectively, of an example all-around gate transistor 120 including a transistor gate stack 100, in accordance with various embodiments. The transistor 120 of FIGS. 9A and 9B may include a channel material 102, and a gate stack 100 including a gate electrode material 108, and a high-k dielectric 106 and an insulator material 104. The insulator material 104 may be disposed between the high-k dielectric 106. In the all-around gate transistor 120 illustrated in FIGS. 9A and 9B, a wire 136 formed of a semiconductor material may extend above a substrate 134 and a layer of oxide material 130. The wire 136 may take the form of a nanowire or nanoribbon, for example. The gate stack 100 may wrap entirely or almost entirely around the wire 136, as shown, with the channel material 102 corresponding to the portion of the wire 136 wrapped by the gate stack 100. In particular, the insulator material 104 may wrap around the channel material 102 of the fin 132, the high-k dielectric 106 may wrap around the insulator material 104, and the gate electrode material 108 may wrap around the high-k dielectric 106. In some embodiments, the gate stack 100 may fully encircle the wire 136. The wire 136 may include a source region 116 and a drain region 118 on either side of the gate stack 100, as shown. The composition of the channel material 102, the source region 116, and a drain region 118 may take the form of any of the embodiments disclosed herein, or known in the art. Although the wire 136 illustrated in FIGS. 9A and 9B is shown as having a rectangular cross section, the wire 136 may instead have a cross section that is rounded or otherwise irregularly shaped, and the gate stack 100 may conform to the shape of the wire 136. In use, the tri-gate transistor 120 may form conducting channels on more than three “sides” of the wire 136, potentially improving performance relative to tri-gate transistors. Although FIGS. 9A and 9B depict an embodiment in which the longitudinal axis of the wire 136 runs substantially parallel to a plane of the oxide material 130 (and a plane of the substrate 134), this need not be the case; in other embodiments, for example, the wire 136 may be oriented “vertically” so as to be perpendicular to a plane of the oxide 130 (or plane of the substrate 134).

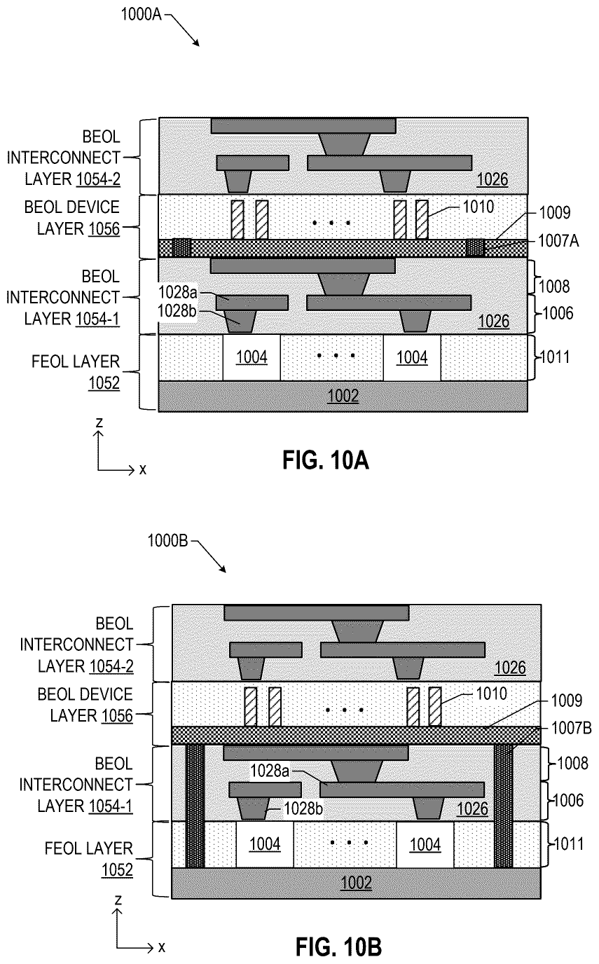

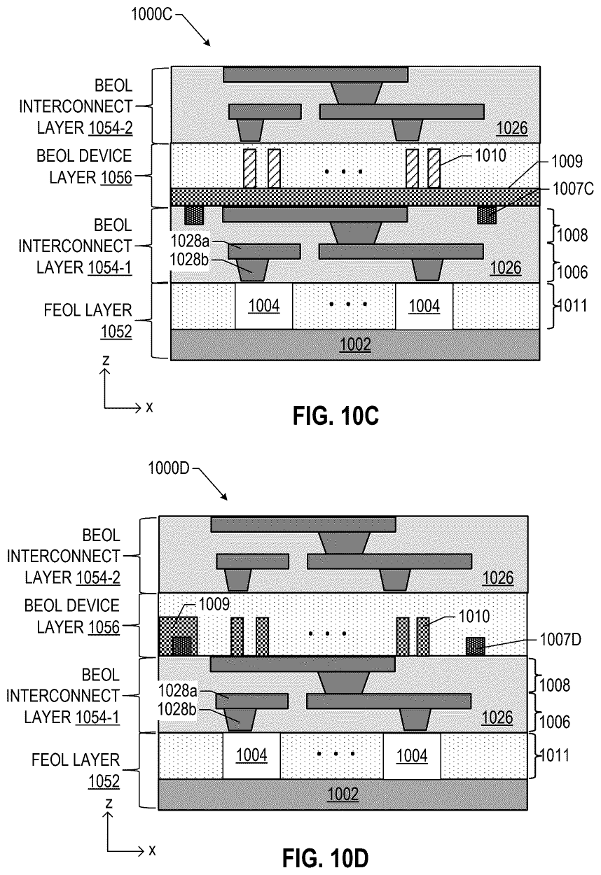

FIGS. 10A-10D illustrate example IC structures in which backend transistors fabricated using seeded epitaxial growth may be implemented. The IC structures 1000A-1000D of FIGS. 10A-10D include one or more FEOL layers, depicted as the FEOL layer 1052, and one or more BEOL layers over the FEOL layers, depicted in FIGS. 10A-10D as BEOL interconnect layers 1054-1, 1054-2 and a BEOL device layer 1056.

The FEOL layer 1052 may include a plurality of FEOL devices 1004, e.g., frontend transistors such as FinFETs, nanowire transistors, nanoribbon transistors, etc. in a device region 1011 over a support structure or substrate 1002. The substrate 1002 may be an example of the support 122 discussed above. The BEOL device layer 1056 includes a plurality of BEOL devices 1010, e.g., backend transistors such as FinFETs, nanowire transistors, nanoribbon transistors, etc. Backend devices 1010 of the BEOL device layer 1056 are represented in FIGS. 10A-10D as fins of a semiconductor material, however, the backend devices 1010 of the BEOL device layer 1056 may include transistors of any transistor architecture, such as those described above with respect to FIGS. 1-9B. In some examples, the FEOL layer 1052 and/or the BEOL device layer 1056 may also include an array of memory cells. Transistors implemented in the FEOL layer 1052 and/or in the BEOL device layer 1056 may be logic transistors or access transistors for memory cells. The BEOL interconnect layers 1054-1, 1054-2 may include a plurality of backend interconnects electrically coupled to (e.g., in electrically conductive contact with at least portions of) one or more of the plurality of FEOL devices 1004 of the FEOL layer 1052 and/or one or more of the plurality of backend devices 1010 of the BEOL device layer 1056.

Various BEOL interconnect layers 1054-1, 1054-2 may be/include one or more metal layers of a metallization stack of the IC device. For example, the BEOL interconnect layer 1054-1 is shown as having two interconnect/metal layers 1006, 1008. Various metal layers of the BEOL interconnect layers 1054 may be used to interconnect the various inputs and outputs of the logic devices in the compute logic of the FEOL layer 1052 and/or of the BEOL device layer 1056. In one example, each of the BEOL interconnect layers may include a via portion 1028b and a line or trench/interconnect portion 1028a. The trench portion 1028a of a metal layer is configured for transferring signals and power along electrically conductive (e.g., metal) lines (also sometimes referred to as “trenches”) extending in the x-y plane (e.g., in the x or y directions), while the via portion 1028b of a metal layer is configured for transferring signals and power through electrically conductive vias extending in the z-direction, e.g., to any of the adjacent metal layers above or below. Accordingly, in one example, vias connect metal structures (e.g., metal lines or vias) from one metal layer to metal structures of an adjacent metal layer. While referred to as “metal” layers, various layers of the BEOL interconnect layers 1054 may include only certain patterns of conductive metals, e.g., copper (Cu), aluminum (Al), tungsten (W), or cobalt (Co), or metal alloys, or more generally, patterns of an electrically conductive material, formed in an insulating medium such as an ILD 1026. The insulating medium may include any suitable ILD materials such as silicon oxide, carbon-doped silicon oxide, silicon carbide, silicon nitride, aluminum oxide, and/or silicon oxynitride.

In some examples, the channel material for the backend devices 1010 is epitaxially grown based on seed structures. For example, the IC structures 1000A-1000D of FIGS. 10A-10D include a plurality of seed structures in a layer in and/or under the backend devices 1010. For example, FIG. 10A includes a plurality of seed structures 1007A over the BEOL interconnect layer 1054-1 (e.g., over and/or on the ILD 1026 of the BEOL interconnect layer 1054-1). In one example, the seed structures 1007A include a semiconductor material, e.g., a single crystal/monocrystalline semiconductor material. Although a material may be referred to as monocrystalline or single crystal, one of ordinary skill will appreciate that crystal defects may be present (e.g., as artifacts of an imperfect epitaxial growth process). In the example illustrated in FIG. 10A, another semiconductor material 1009 is present in the same layer as the seed structures 1007A. In one example, the layer of semiconductor material 1009 has a thickness in a range of 10-100 nanometers, where the thickness is a dimension of the semiconductor material 1009 in a plane substantially orthogonal to the interconnect layers 1056 and substrate 1002.

In one such example, the semiconductor material 1009 is deposited in a process after the seed structures 1007A are provided, so that the semiconductor material 1009 has a crystal orientation that is based on the crystal orientation of the seed structures 1007A. In one example, one of the plurality of seed structures 1007A has a first crystal orientation, and the semiconductor material 1009 has a second crystal orientation that is substantially the same as the first crystal orientation. “Crystal orientation” or “crystal lattice orientation” refers to the crystal lattice structure and orientation of a crystalline material, e.g., the orientation of crystal planes of a crystal lattice. A crystal surface or crystal plane may be defined based on how the crystal plane intercepts the crystallographic axes of the crystalline material. Two materials may have the same (e.g., substantially the same) crystal orientation if a crystal plane defined by the same miller indices in each of the materials has about the same orientation. For example, a first material with a crystal orientation may have substantially the same crystal orientation as a second material with a second crystal orientation if the first crystal orientation is within a few degrees (e.g., 0-5 degrees) of the second crystal orientation.

Thus, the layer of semiconductor material 1009 has a crystal orientation that is substantially the same as the seed structures 1007A. The semiconductor material 1009 can be a single crystal semiconductor material or polycrystalline. In an example in which the semiconductor material 1009 is polycrystalline, the layer of the semiconductor material 1009 includes multiple crystals and grain boundaries between crystals. In one such example, a plurality of crystals in a polycrystalline semiconductor material have about the same crystal orientation as the seed structures 1007A; however, in an example in which the semiconductor material 1009 is a polycrystalline material, some misorientations are possible between different grain boundaries.

In one example, the layer of the semiconductor material 1009 is used to epitaxially grow another layer of semiconductor material from which the channel regions of transistors are formed in a later process. For example, referring to FIG. 10A, the backend devices 1010 include a semiconductor material (e.g., channel material) that is epitaxially grown on the semiconductor material 1009. Thus, in one example, the channel material of the backend devices 1010 has about the same crystal orientation as the layer of semiconductor material 1009 and the seed structures 1007A. In one such example, the layer of semiconductor material 1009 acts as a textured template or structured template to enable epitaxially growing a layer of semiconductor material from which transistor channel regions are formed.

The seed structures 1007A, the semiconductor material 1009, and the channel material of the backend devices 1010 may include any of the semiconductor materials discussed above (e.g., silicon, silicon germanium, germanium, IGZO, etc.). In one example, the seed structures 1007A, semiconductor material 1009, and the channel material of the backend devices 1010 may have material compositions that are the same or different as long as the lattices are sufficiently matched with one another to enable forming a textured template of the semiconductor material 1009 from the seed structures 1007A, and to enable epitaxially growing the channel material of the backend devices 1010 from the textured template of the semiconductor material 1009. In one example, the seed structures 1007A may have a first material composition and a first lattice constant, and the semiconductor material 1009 may have a second material composition and a second lattice constant, where the first and second lattice constants are matched within about 10% of one another (e.g., first lattice constant is in a range of about +−10% of the second lattice constant). In one example, the seed structures 1007A and the semiconductor material 1009 have material compositions (e.g., in terms of the constituent elements) within about 30% of one another. Similarly, the semiconductor material 1009 and the channel material of the backend devices 1010 have material compositions within about 30% of one another, and lattice constants that are matched within about 10% of one another.

Thus, each of the IC structures 1000A-1000D of FIGS. 10A-10D include seed structures over or through an interconnect layer and backend transistors formed over a layer with the seed structures. The IC structures 1000A-1000C of FIGS. 10A-10C differ from one another in terms of the location and dimensions of the seed structures. The IC structure 1000D of FIG. 10D differs from the IC structures 1000A-1000C of FIGS. 10A-10C in that the IC structure 1000D lacks a separate semiconductor layer between the seed structures and the semiconductor material from which the transistor channels are formed (e.g., in the IC structure 1000D, the channel material is the semiconductor material 1009 rather than being a separate semiconductor material that is epitaxially grown from the semiconductor material 1009).

As can be seen in FIG. 10A, the seed structures 1007A are provided over the interconnect layer 1054 (e.g., via a chemical vapor deposition (CVD) or physical vapor deposition (PVD) process). For example, the seed structures 1007A are in the same layer or plane as the semiconductor material 1009, which is over the BEOL interconnect layer 1054-1. For example, the seed structure 1007A may include a monocrystalline layer on the insulator material 1026 of the BEOL interconnect layer 1054-1. In contrast, in the IC structure 1000B of FIG. 10B, the seed structures 1007B pass through the BEOL interconnect layer 1054-1 and the device region 1011 of the FEOL layer 1052. In one such example, the seed structures 1007B are epitaxially grown from a FEOL layer 1052 (e.g., from the substrate 1002 or from another layer in the device region 1011). In one such example, the seed structures 1007B may be referred to as epitaxial structures. In one example, the seed structures 1007B include a continuous monocrystalline layer of a semiconductor material through the interconnect layer 1054-1 and in contact with a layer in the device region 1011. In an example where the seed structures 1007B are epitaxially grown from a FEOL layer 1052, the height may be greater than seed structures provided with a CVD or PVD process (e.g., due to extending through the device region and extending through one or more interconnect layers), where the height is a dimension of the seed structure in a plane substantially orthogonal to the interconnect layer 1054-1 or the substrate 1002 (e.g., along the z-axis as shown in FIG. 10D).

FIG. 10C illustrates an example IC structure 1000C that includes seed structures 1007C in an insulator material (e.g., the ILD 1026) of the BEOL interconnect layer 1054-1 (but not extending entirely through the interconnect layer 1054-1, like in the IC structure 1000B of FIG. 10B). In one such example, the seed structures 1007C may be deposited (e.g., via a CVD or PVD process) in openings in the ILD 1026. In the example IC structures 1000B and 1000C of FIGS. 10B and 10C, the seed structures 1007B, 1007C are in a first plane and the semiconductor material 1009 is in a second plane over the first plane, where the first plane and the second plane are substantially parallel to the interconnect layer 1054-1.

FIG. 10D illustrates an example IC structure 1000D in which portions of the semiconductor material 1009 are or include channel regions of backend transistors 1010. Therefore, as can be seen in FIG. 10D, a layer of the semiconductor material 1009 may be deposited over seed structures 1007D, and then patterned (e.g., into fins of semiconductor material) to form channel regions of backend transistors 1010. In one such example, the seed structures 1007D may be implemented in accordance with any other example discussed herein (e.g., the seed structures 1007D may be epitaxially grown semiconductor structures that extend through the interconnect layer 1054-1). The semiconductor material 1009 may be absent or present over the seed structures 1007D in the final IC structure. For example, the IC structure 1000D includes a layer of the semiconductor material 1009 over the seed structure 1007D on the left side of FIG. 10D, while the semiconductor material 1009 is absent over the seed structures 1007D on the right side of FIG. 10D.

Thus, FIGS. 10A-10D illustrate various examples of IC structures that include an interconnect layer over a device region, where the interconnect layer includes an insulator material and a conductive interconnect in the insulator material. A semiconductor structure (e.g., a seed structure) is present over and/or through the interconnect layer, where the semiconductor structure includes a first semiconductor material with a first crystal lattice orientation. A second semiconductor material (e.g., the semiconductor material used for the transistor channel regions) is present over the semiconductor structure, and the second semiconductor material has a second crystal lattice orientation that is substantially the same as the first crystal lattice orientation. In one such example, a portion of the second semiconductor material is a channel region of a transistor. The example IC structures 1000A-1000C of FIGS. 10A-10C also include a third semiconductor material (e.g., a textured template) between the second semiconductor material and the interconnect layer, where the third semiconductor material has a third crystal lattice orientation that is substantially the same as the first crystal lattice orientation. Although the example IC devices 1000A-1000D illustrate two interconnect layers 1006, 1008 under the BEOL device layer 1056 and two interconnect layers (e.g., the metal layers of the BEOL interconnect layer 1054-2) over the BEOL device layer 1056, IC devices may include a different number (e.g., more than or fewer than) the number of interconnect layers shown. Also, devices may be present in interconnect layers, and interconnect may be present in device layers (e.g., the BEOL device layer 1056) or in the device region 1011.

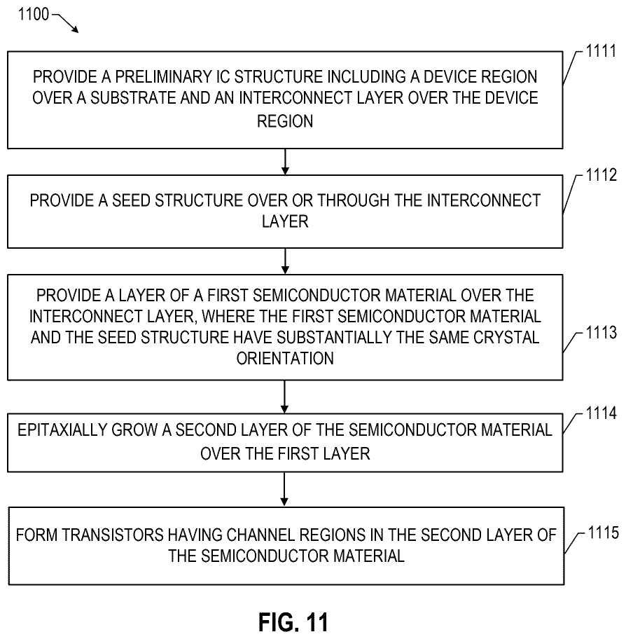

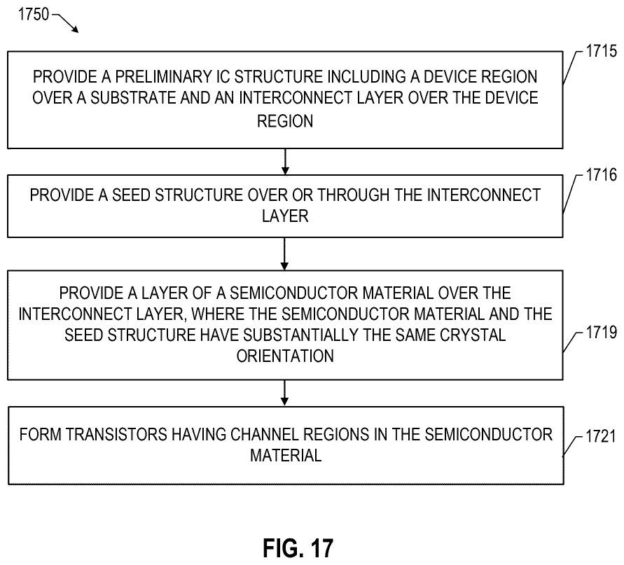

FIGS. 11 and 17 are flow diagrams of example methods for fabricating an IC device including backend transistors, in accordance with some embodiments. Although the operations of the methods of FIGS. 11 and 17 are illustrated once each and in a particular order, the operations may be performed in any suitable order and repeated as desired. For example, one or more operations may be performed in parallel to fabricate multiple IC structures using differentiated transistor isolation techniques substantially simultaneously. In another example, the operations may be performed in a different order to reflect the structure of an IC device in which backend transistors will be implemented.

In addition, the example fabricating methods of FIGS. 11 and 17 may include other operations not specifically shown in FIGS. 11 and 17, such as various cleaning or planarization operations as known in the art. For example, in some embodiments, a support, as well as layers of various other materials subsequently deposited thereon, may be cleaned prior to, after, or during any of the processes of the methods described herein, e.g., to remove oxides, surface-bound organic and metallic contaminants, as well as subsurface contamination. In some embodiments, cleaning may be carried out using e.g., a chemical solutions (such as peroxide), and/or with ultraviolet (UV) radiation combined with ozone, and/or oxidizing the surface (e.g., using thermal oxidation) then removing the oxide (e.g., using hydrofluoric acid (HF)). In another example, the intermediate IC structures described herein may be planarized prior to, after, or during any of the processes of the methods of FIGS. 11 and 17 described herein, e.g., to remove overburden or excess materials. In some embodiments, planarization may be carried out using either wet or dry planarization processes, e.g., planarization be a chemical mechanical planarization (CMP), which may be understood as a process that utilizes a polishing surface, an abrasive and a slurry to remove the overburden and planarize the surface.

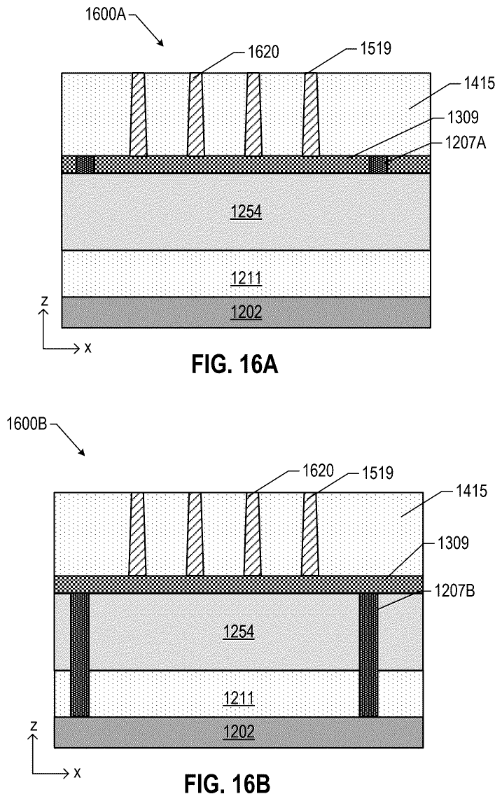

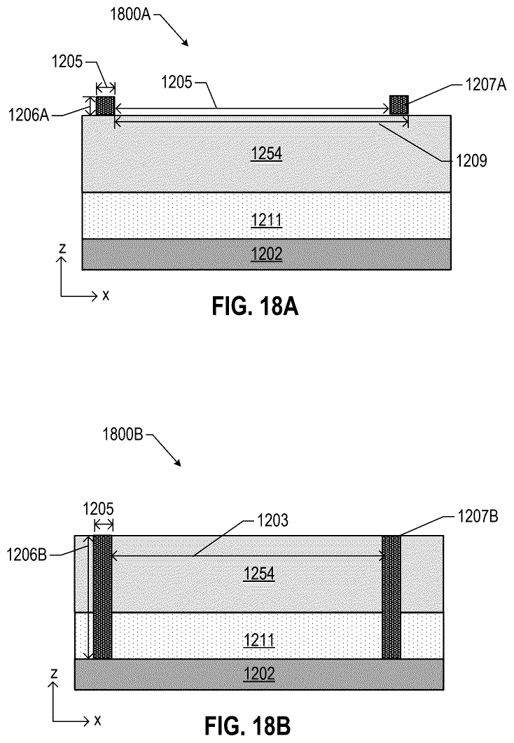

FIGS. 12A-12B, 13A-13B, 14A-14B, and 15A-15B provide different views at various stages in the fabrication of an example IC structure according to the method of FIG. 11, in accordance with some embodiments. FIGS. 16A-16B illustrates another example IC structure fabricated according to the method of FIG. 11. FIGS. 18A-18B, 19A-19B, and 20A-20B provide cross-sectional side views at various stages in the fabrication of an example IC structure according to the method of FIG. 17. FIGS. 12-16 and 18-20 include figures labeled with letters A and B (e.g., FIG. 12 includes FIGS. 12A and 12B), providing views of different IC structure including different seed structures. In particular, those figures of FIGS. 12-16 and 18-20 labeled with a letter A (e.g., FIG. 12A) illustrate a cross-sectional side view of a portion of an IC structure that includes a seed structure over an interconnect layer. Those figures of FIGS. 12-16 and 18-20 labeled with a letter B (e.g., 12B) illustrate a cross-sectional side view of a portion of an IC structure that includes a seed structure that extends through the interconnect layer.

Turning to FIG. 11, the method 1100 begins with a process 1111 of providing a preliminary IC structure including a device region over a substrate and an interconnect layer over the device region. The method 1100 continues with a process 1112 of providing a seed structure over or through the interconnect layer. The IC structures 1200A and 1200B of FIGS. 12A-12B illustrate example results of the processes 1111 and 1112. As can be seen in FIGS. 12A-12B, the IC structures 1200A and 1200B each include a substrate 1202, a device region 1211 over the substrate, and an interconnect layer 1254 over the device region 1211. The substrate 1202 may be an example of the support 122 or substrate 134 discussed above. The device region 1211 may be an example of the device region 1011, and the interconnect layer 1254 may be an example of the BEOL interconnect layer 1054-1 discussed above with respect to FIGS. 10A-10D.

FIG. 12A illustrates an example IC structure 1200A in which seed structures 1207A are provided over the interconnect layer 1254. In one example, the seed structures 1207A may be in contact with an insulator material of the interconnect layer 1254. In one example, the seed structures 1207A may be provided with any suitable deposition techniques, such as atomic layer deposition (ALD), CVD, plasma enhanced CVD (PECVD), or/and PVD processes such as sputter. FIG. 12B illustrates an example IC structure 1200B in which the seed structures 1207B are provided through the interconnect layer 1254 and in contact with and/or through a layer in the device region 1211. In the example illustrated in FIG. 12B, the seed structures 1207B extend through the device region 1211 to the substrate 1202. In one example, providing the seed structures 1207B involves forming openings through the interconnect layers and one or more layers of the device region 1211, and epitaxially growing the seed structures 1207B based on a semiconductor material in the device region or of the substrate 1202. In one such example, the height 1206B of the epitaxially grown seed structures 1207B may be greater than the height 1206A of seed structures 1207A provided via another process. In one example, the seed structures 1207A, 1207B are single crystal structures, at least a portion of which is exposed over the interconnect layer 1254.

In the examples illustrated in FIGS. 12A and 12B, the seed structures 1207A, 1207B include a plurality of seed structures that have a pitch (e.g., along the x-axis as illustrated in FIGS. 12A-12B). For example, the seed structures 1207A, 1207B may be provided with about the same distance 1203 between adjacent seed structures along the x-axis. In one example, adjacent seed structures 1207A are separated from one another by a distance in a range of about 500 nanometers to 300 microns. In the examples illustrated in FIGS. 12A and 12B, the seed structures 1207A, 1207B have a pitch 1209 (where the pitch is equal to the distance 1203 between adjacent seed structures plus the width 1205 of a seed structure). In some examples, the seed structures may be provided in an array of seed structures that have a pitch along both the x-axis and along the y-axis (where the y-axis is going into and coming out of the page as illustrated in FIGS. 12A, 12B). In other examples, the seed structures 1207A, 1207B are provided in a single line instead of an array. The number and arrangement of seed structures may depend on factors such as the desired location and density of backend transistors.

In one example, the width 1205 of the seed structures provided may depend on, e.g., the number and spacing of the seed structures. For example, the seed structures are provided with a sufficiently large width to enable a subsequently deposited semiconductor layer to have the substantially same crystal orientation as the seed structures. In one example, the width 1205 is between about 10-50% of the pitch, or about 10-30% of the pitch; however, other widths are possible (e.g., less than 10% of the pitch or more than 50% of the pitch).

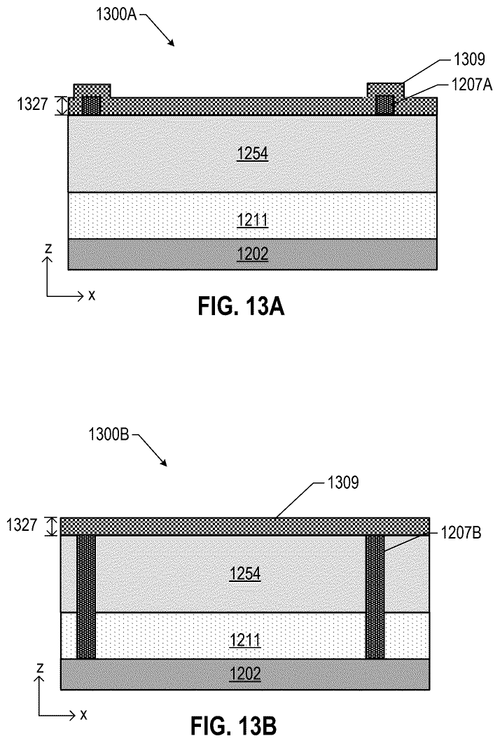

Referring again to FIG. 11, the method 1100 continues with the process 1113 of providing a layer of a first semiconductor material over the interconnect layer, where the first semiconductor material and the seed structure have substantially the same crystal orientation. The IC structures 1300A and 1300B of FIGS. 13A-13B illustrate example results of the process 1113. As can be seen in FIGS. 13A-13B, the IC structures 1300A and 1300B include a layer of a semiconductor material 1309 over the interconnect layer 1254. In the example in FIG. 13A, the semiconductor material 1309 may be provided as a conformal layer over the interconnect layer and on a top exposed surface of the seed structures 1207A. In the example illustrated in FIG. 13A, the semiconductor material 1309 is also present on sidewalls of the seed structures 1207A. In the example in FIG. 13B, the semiconductor material 1309 is provided on top exposed surfaces of the seed structures 1207B, but not on sidewalls of the seed structures 1207B. In one example, the thickness 1327 of the semiconductor material 1309 is in a range of 5-100 nanometers.

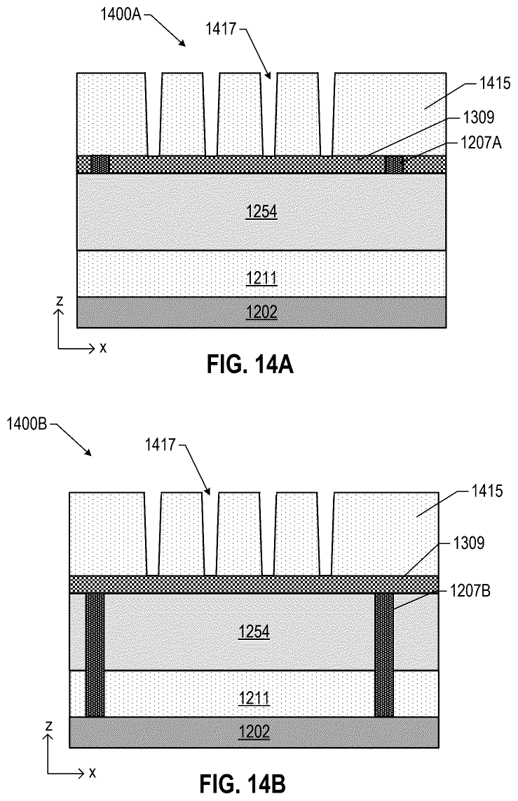

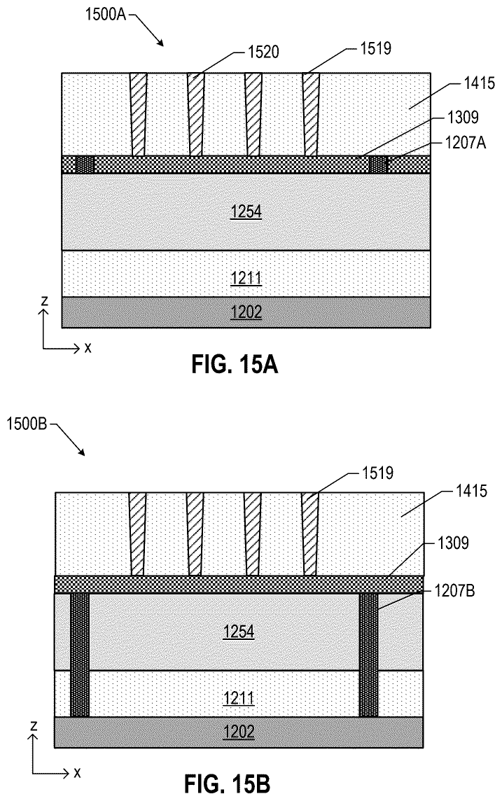

Referring again to FIG. 11, the method 1100 continues with the process 1114 of epitaxially growing a second semiconductor material over the layer of the first semiconductor material. The IC structures 1400A, 1400B of FIGS. 14A-14B and the structures 1500A, 1500B of FIGS. 15A-15B illustrate example results of the process 1114. In one example epitaxially growing a second semiconductor material over the first semiconductor material may involve providing and patterning an insulator material followed by epitaxially growing the second semiconductor material in the openings. As can be seen in FIGS. 14A-14B, the IC structures 1400A, 1400B include a layer of an insulator material 1415 over the semiconductor material 1309, with openings 1417 in the insulator material 1415. The insulator material 1415 may be any suitable insulator material, such as those discussed above. The semiconductor material 1309 is exposed at bottoms of the openings 1417.

The second semiconductor material may then be epitaxially grown from the exposed semiconductor material 1309 at the bottom of the openings 1417, as illustrated in FIGS. 15A, 15B. As can be seen in FIGS. 15A and 15B, the IC structures 1500A and 1500B include a second semiconductor material 1519 in the openings 1417 over the semiconductor material 1309. The semiconductor material 1309 can thus provide a textured template for epitaxially growing the second semiconductor material 1519. Accordingly, in one example, the seed structures 1207A, 1207B, the semiconductor material 1309, and the second semiconductor material 1519 have substantially the same crystal orientation. Although only a single second semiconductor material 1519 is shown, in other examples, more than one semiconductor material may be grown over the semiconductor material 1309. For example, a stack of alternating layers of different semiconductor materials may be grown (e.g., to form nanoribbon transistors with subsequent processes).

In another example, a layer of the second semiconductor material may be grown, followed by patterning the second semiconductor material and then followed by deposition of an insulator material. In an example in which a layer of the second semiconductor material is first grown and then patterned, the taper of the patterned channel material will be opposite of the taper when the channel material is epitaxially grown in openings in an ILD, such as shown in FIGS. 14A-14B and 15A-15B. FIGS. 16A and 16B illustrate example IC structures 1600A, 1600B resulting from a process of first epitaxially growing the later of the second semiconductor material 1519 followed by patterning the second semiconductor material 1519. As can be seen in FIGS. 16A and 16B, the fins 1620 have a taper in an opposite direction compared to the fins 1520 of FIGS. 15A and 15B. For example, the fins 1520 have a width proximate to the top of the fins 1520 that is greater than a width proximate to a bottom of the fins 1520, where the width is a dimension of the fins in a plane substantially parallel to the substrate 1202, and where the “bottom” of the fins 1520 is in contact with the semiconductor material 1309 and closer to the device region 1211 than the “top” of the fins 1520. In contrast, the fins 1620 have a width proximate to the top of the fins 1620 that is smaller than a width proximate to a bottom of the fins 1620.

Referring again to FIG. 11, the method 1100 continues with the process 1115 of forming transistors having channel regions in the second semiconductor material. In the example illustrated in FIGS. 15A, 15B, the second semiconductor material is patterned into fins 1520 (e.g., for forming FinFETs or nanoribbon transistors), however, as explained above, the epitaxially grown semiconductor material 1519 may be the channel material of transistors of any architecture.

Thus, the method 1100 of FIG. 11 illustrates a method of forming backend transistors, including seeded epitaxial growth techniques. In another example, channel regions of transistors may be formed from the layer of the first semiconductor material provided over the seed structures (rather than using the layer of the first semiconductor material as a template to epitaxially grow the channel material). FIG. 17 illustrates a method 1750 of forming backend transistors in which the channel regions of the backend transistors are in portions of the first semiconductor material.

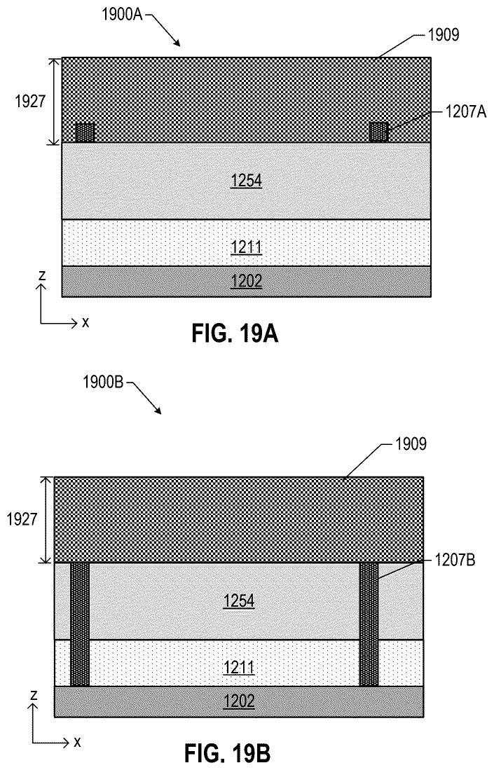

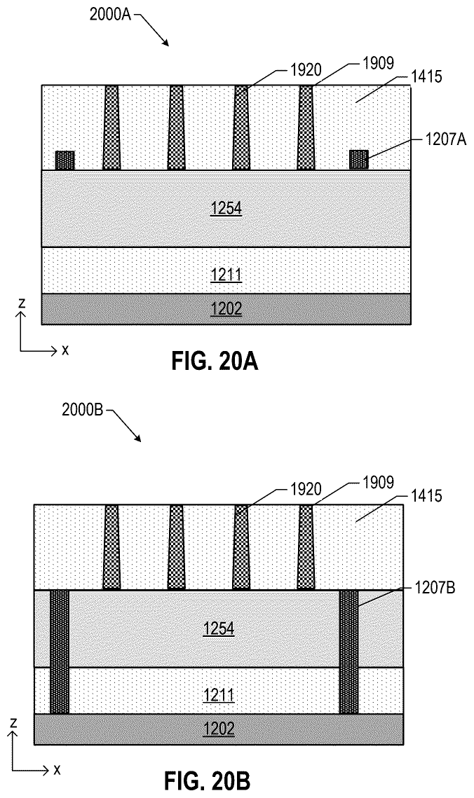

The method 1750 begins with a process 1715 of providing a preliminary IC structure including a device region over a substrate and an interconnect layer over the device region, and a process 1716 of providing a seed structure over or through the interconnect layer. The IC structures 1800A and 1800B of FIGS. 18A-18B illustrate example results of the processes 1715 and 1716. As can be seen in FIGS. 18A-18B, the IC structures 1800A and 1800B each include a substrate 1202, a device region 1211 over the substrate, an interconnect layer 1254 over the device region 1211, and seed structures 1207A, 1207B, which are described above with respect to FIGS. 12A and 12B. The method 1750 continues with a process 1719 of providing a layer of a semiconductor material over the interconnect layer, where the semiconductor material and the seed structure have substantially the same crystal orientation. The IC structures 1900A and 1900B of FIGS. 19A-19B illustrate example results of the process 1719. As can be seen in FIGS. 19A-19B, the IC structures 1900A and 1900B include a layer of a semiconductor material 1909 over the interconnect layer 1254. In the example illustrated in FIGS. 19A, 19B, the thickness 1927 of the semiconductor material 1909 may be greater when the semiconductor material 1909 is to be used as a channel material than when the semiconductor material is used as a textured template to aid in epitaxially growing the channel material. The method 1750 continues with a process 1721 of forming transistors having channel regions in the semiconductor material. In one example, forming transistors having channel regions in the semiconductor material may involve patterning the semiconductor material 1909 and providing an insulator material over the patterned semiconductor material 1909. The IC structures 2000A and 2000B of FIGS. 20A-20B illustrate example results of the process 1721. As can be seen in FIGS. 20A-20B, the IC structures 2000A and 2000B include patterned fins 1920 of the semiconductor material 1909 surrounded by an insulator material 1415.

Thus, FIGS. 11 and 17 illustrate example methods for forming backend transistors. Performing the method 1100 of FIG. 11 may result in features in the final IC structures that are characteristic of the use of the method 1100. For example, one such feature is illustrated in the IC structures 1000A-1000C shown in FIGS. 10A-10C, which shows seed structures over (and/or through) an interconnect layer, a layer of a semiconductor material over the seed structures, and a channel material over the layer of semiconductor material, where the seed structures, the semiconductor material, and the channel material have substantially the same crystal orientation as one another. Performing the method 1750 of FIG. 17 may result in features in the final IC structures that are characteristic of the use of the method 1750. For example, one such feature is illustrated in the IC structure 1000D shown in FIG. 10D, which shows seed structures over (and/or through) an interconnect layer, and a channel material over the seed structures, where the channel material and the seed structures have substantially the same crystal orientation.

IC structures with backend transistors fabricated in accordance with techniques described herein may be included in any suitable electronic component or electronic device. FIGS. 21-24 illustrate various examples of apparatuses that may include one or more of the IC structures with IC structures with backend transistors disclosed herein.

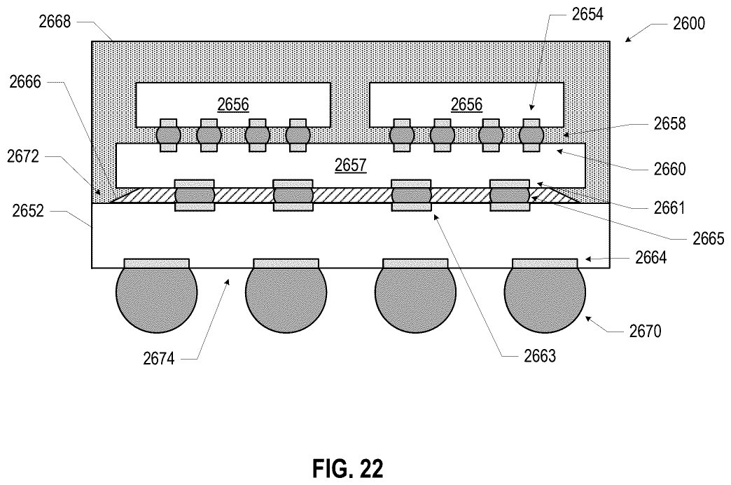

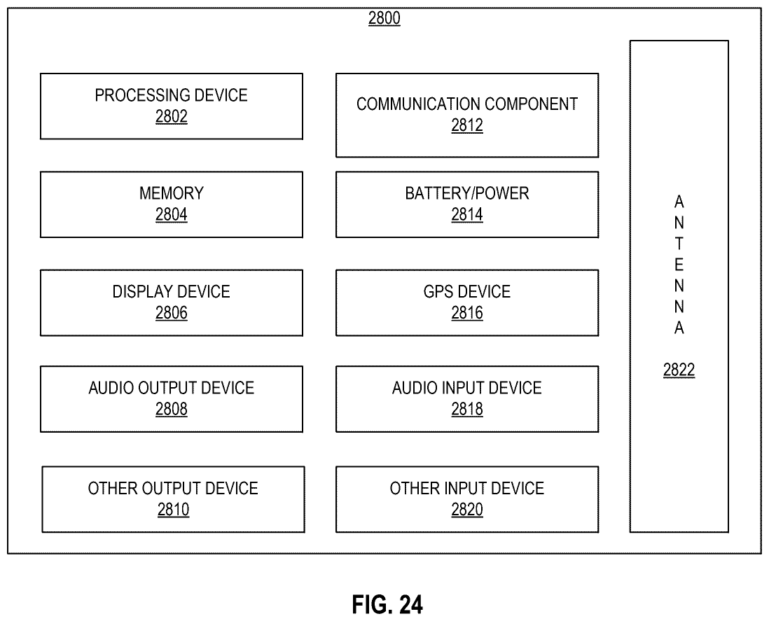

FIG. 21 illustrates top views of a wafer 2500 and dies 2502 that may include one or more IC structures with backend transistors fabricated using seeded epitaxial growth techniques in accordance with any of the embodiments disclosed herein. In some embodiments, the dies 2502 may be included in an IC package, in accordance with any of the embodiments disclosed herein. For example, any of the dies 2502 may serve as any of the dies 2656 in an IC package 2600 shown in FIG. 22. The wafer 2500 may be composed of semiconductor material and may include one or more dies 2502 having IC structures formed on a surface of the wafer 2500. Each of the dies 2502 may be a repeating unit of a semiconductor product that includes any suitable IC (e.g., ICs including one or more IC structures with backend transistors fabricated using seeded epitaxial growth techniques as described herein). After the fabrication of the semiconductor product is complete (e.g., after manufacture of any embodiment of an IC device with backend transistors fabricated using seeded epitaxial growth techniques as described herein), the wafer 2500 may undergo a singulation process in which each of the dies 2502 is separated from one another to provide discrete “chips” of the semiconductor product. In particular, devices that include one or more IC structures with backend transistors fabricated using seeded epitaxial growth techniques as disclosed herein may take the form of the wafer 2500 (e.g., not singulated) or the form of the die 2502 (e.g., singulated). The die 2502 may include supporting circuitry to route electrical signals to various memory cells, transistors, capacitors, as well as any other IC components. In some embodiments, the wafer 2500 or the die 2502 may implement or include a memory device (e.g., a hysteretic memory device), a logic device (e.g., an AND, OR, NAND, or NOR gate), or any other suitable circuit element. Multiple ones of these devices may be combined on a single die 2502. For example, a memory array formed by multiple memory devices may be formed on a same die 2502 as a processing device (e.g., the processing device 2802 of FIG. 24) or other logic that is configured to store information in the memory devices or execute instructions stored in the memory array.

FIG. 22 is a side, cross-sectional view of an example IC package 2600 that may include one or more IC structures with backend transistors fabricated using seeded epitaxial growth techniques in accordance with any of the embodiments disclosed herein. In some embodiments, the IC package 2600 may be a system-in-package (SiP).

The package substrate 2652 may be formed of a dielectric material (e.g., a ceramic, a buildup film, an epoxy film having filler particles therein, etc.), and may have conductive pathways extending through the dielectric material between the face 2672 and the face 2674, or between different locations on the face 2672, and/or between different locations on the face 2674.

The package substrate 2652 may include conductive contacts 2663 that are coupled to conductive pathways through the package substrate 2652, allowing circuitry within the dies 2656 and/or the interposer 2657 to electrically couple to various ones of the conductive contacts 2664 (or to other devices included in the package substrate 2652, not shown).

The IC package 2600 may include an interposer 2657 coupled to the package substrate 2652 via conductive contacts 2661 of the interposer 2657, first-level interconnects 2665, and the conductive contacts 2663 of the package substrate 2652. The first-level interconnects 2665 illustrated in FIG. 22 are solder bumps, but any suitable first-level interconnects 2665 may be used. In some embodiments, no interposer 2657 may be included in the IC package 2600; instead, the dies 2656 may be coupled directly to the conductive contacts 2663 at the face 2672 by first-level interconnects 2665.

The IC package 2600 may include one or more dies 2656 coupled to the interposer 2657 via conductive contacts 2654 of the dies 2656, first-level interconnects 2658, and conductive contacts 2660 of the interposer 2657. The conductive contacts 2660 may be coupled to conductive pathways (not shown) through the interposer 2657, allowing circuitry within the dies 2656 to electrically couple to various ones of the conductive contacts 2661 (or to other devices included in the interposer 2657, not shown). The first-level interconnects 2658 illustrated in FIG. 22 are solder bumps, but any suitable first-level interconnects 2658 may be used. As used herein, a “conductive contact” may refer to a portion of electrically conductive material (e.g., metal) serving as an interface between different components; conductive contacts may be recessed in, flush with, or extending away from a surface of a component, and may take any suitable form (e.g., a conductive pad or socket).

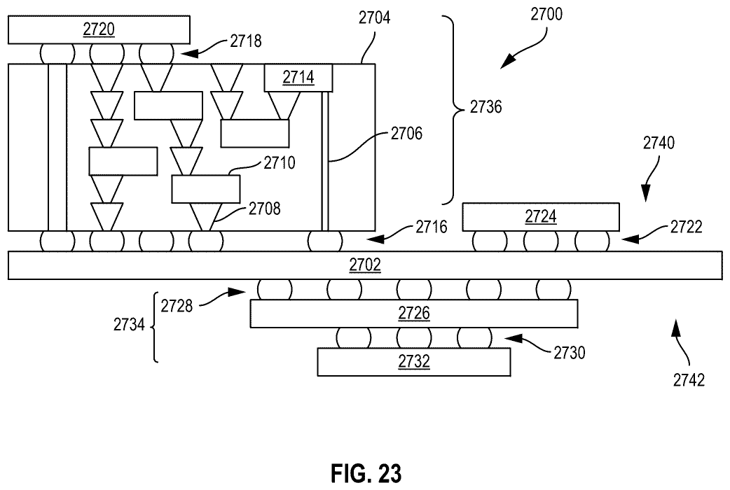

In some embodiments, an underfill material 2666 may be disposed between the package substrate 2652 and the interposer 2657 around the first-level interconnects 2665, and a mold compound 2668 may be disposed around the dies 2656 and the interposer 2657 and in contact with the package substrate 2652. In some embodiments, the underfill material 2666 may be the same as the mold compound 2668. Example materials that may be used for the underfill material 2666 and the mold compound 2668 are epoxy mold materials, as suitable. Second-level interconnects 2670 may be coupled to the conductive contacts 2664. The second-level interconnects 2670 illustrated in FIG. 22 are solder balls (e.g., for a ball grid array arrangement), but any suitable second-level interconnects 2670 may be used (e.g., pins in a pin grid array arrangement or lands in a land grid array arrangement). The second-level interconnects 2670 may be used to couple the IC package 2600 to another component, such as a circuit board (e.g., a motherboard), an interposer, or another IC package, as known in the art and as discussed below with reference to FIG. 23.

The dies 2656 may take the form of any of the embodiments of the die 2502 discussed herein (e.g., may include any of the embodiments of the IC structures with backend transistors fabricated using seeded epitaxial growth techniques as described herein). In embodiments in which the IC package 2600 includes multiple dies 2656, the IC package 2600 may be referred to as a multi-chip package (MCP). The dies 2656 may include circuitry to perform any desired functionality. For example, one or more of the dies 2656 may be logic dies (e.g., silicon-based dies), and one or more of the dies 2656 may be memory dies (e.g., high bandwidth memory), including embedded memory dies as described herein. In some embodiments, any of the dies 2656 may include one or more IC structures with backend transistors fabricated using seeded epitaxial growth techniques, e.g., as discussed above; in some embodiments, at least some of the dies 2656 may not include IC structures with backend transistors fabricated using seeded epitaxial growth techniques.

The IC package 2600 illustrated in FIG. 22 may be a flip chip package, although other package architectures may be used. For example, the IC package 2600 may be a ball grid array (BGA) package, such as an embedded wafer-level ball grid array (eWLB) package. In another example, the IC package 2600 may be a wafer-level chip scale package (WLCSP) or a panel fan-out (FO) package. Although two dies 2656 are illustrated in the IC package 2600 of FIG. 22, an IC package 2600 may include any desired number of the dies 2656. An IC package 2600 may include additional passive components, such as surface-mount resistors, capacitors, and inductors disposed on the first face 2672 or the second face 2674 of the package substrate 2652, or on either face of the interposer 2657. More generally, an IC package 2600 may include any other active or passive components known in the art.

FIG. 23 is a cross-sectional side view of an IC device assembly 2700 that may include components having one or more IC structures with backend transistors fabricated using seeded epitaxial growth techniques in accordance with any of the embodiments disclosed herein. The IC device assembly 2700 includes a number of components disposed on a circuit board 2702 (which may be, e.g., a motherboard). The IC device assembly 2700 includes components disposed on a first face 2740 of the circuit board 2702 and an opposing second face 2742 of the circuit board 2702; generally, components may be disposed on one or both faces 2740 and 2742. In particular, any suitable ones of the components of the IC device assembly 2700 may include any of one or IC structures with backend transistors fabricated using seeded epitaxial growth techniques in accordance with any of the embodiments disclosed herein; e.g., any of the IC packages discussed below with reference to the IC device assembly 2700 may take the form of any of the embodiments of the IC package 2600 discussed above with reference to FIG. 22 (e.g., may include one or more IC structures with backend transistors fabricated using seeded epitaxial growth techniques provided on a die 2656).

In some embodiments, the circuit board 2702 may be a PCB including multiple metal layers separated from one another by layers of dielectric material and interconnected by electrically conductive vias. Any one or more of the metal layers may be formed in a desired circuit pattern to route electrical signals (optionally in conjunction with other metal layers) between the components coupled to the circuit board 2702. In other embodiments, the circuit board 2702 may be a non-PCB substrate.

The IC device assembly 2700 illustrated in FIG. 23 includes a package-on-interposer structure 2736 coupled to the first face 2740 of the circuit board 2702 by coupling components 2716. The coupling components 2716 may electrically and mechanically couple the package-on-interposer structure 2736 to the circuit board 2702, and may include solder balls (e.g., as shown in FIG. 23), male and female portions of a socket, an adhesive, an underfill material, and/or any other suitable electrical and/or mechanical coupling structure.

The package-on-interposer structure 2736 may include an IC package 2720 coupled to an interposer 2704 by coupling components 2718. The coupling components 2718 may take any suitable form for the application, such as the forms discussed above with reference to the coupling components 2716. The IC package 2720 may be or include, for example, a die (the die 2502 of FIG. 21), an IC device, or any other suitable component. In particular, the IC package 2720 may include one or more IC structures with backend transistors fabricated using seeded epitaxial growth techniques as described herein. Although a single IC package 2720 is shown in FIG. 23, multiple IC packages may be coupled to the interposer 2704; indeed, additional interposers may be coupled to the interposer 2704. The interposer 2704 may provide an intervening substrate used to bridge the circuit board 2702 and the IC package 2720. Generally, the interposer 2704 may spread a connection to a wider pitch or reroute a connection to a different connection. For example, the interposer 2704 may couple the IC package 2720 (e.g., a die) to a BGA of the coupling components 2716 for coupling to the circuit board 2702. In the embodiment illustrated in FIG. 23, the IC package 2720 and the circuit board 2702 are attached to opposing sides of the interposer 2704; in other embodiments, the IC package 2720 and the circuit board 2702 may be attached to a same side of the interposer 2704. In some embodiments, three or more components may be interconnected by way of the interposer 2704.

The interposer 2704 may be formed of an epoxy resin, a fiberglass-reinforced epoxy resin, a ceramic material, or a polymer material such as polyimide. In some implementations, the interposer 2704 may be formed of alternate rigid or flexible materials that may include the same materials described above for use in a semiconductor substrate, such as silicon, germanium, and other group III-V and group IV materials. The interposer 2704 may include metal interconnects 2708 and vias 2710, including but not limited to through-silicon vias (TSVs) 2706. The interposer 2704 may further include embedded devices 2714, including both passive and active devices. Such devices may include, but are not limited to, capacitors, decoupling capacitors, resistors, inductors, fuses, diodes, transformers, sensors, electrostatic discharge (ESD) protection devices, and memory devices. More complex devices such as RF devices, power amplifiers, power management devices, antennas, arrays, sensors, and microelectromechanical systems (MEMS) devices may also be formed on the interposer 2704. The package-on-interposer structure 2736 may take the form of any of the package-on-interposer structures known in the art.

The IC device assembly 2700 may include an IC package 2724 coupled to the first face 2740 of the circuit board 2702 by coupling components 2722. The coupling components 2722 may take the form of any of the embodiments discussed above with reference to the coupling components 2716, and the IC package 2724 may take the form of any of the embodiments discussed above with reference to the IC package 2720.

The IC device assembly 2700 illustrated in FIG. 23 includes a package-on-package structure 2734 coupled to the second face 2742 of the circuit board 2702 by coupling components 2728. The package-on-package structure 2734 may include an IC package 2726 and an IC package 2732 coupled together by coupling components 2730 such that the IC package 2726 is disposed between the circuit board 2702 and the IC package 2732. The coupling components 2728 and 2730 may take the form of any of the embodiments of the coupling components 2716 discussed above, and the IC packages 2726 and 2732 may take the form of any of the embodiments of the IC package 2720 discussed above. The package-on-package structure 2734 may be configured in accordance with any of the package-on-package structures known in the art.

FIG. 24 is a block diagram of an example computing device 2800 that may include one or more components with one or more IC structures with backend transistors fabricated using seeded epitaxial growth techniques in accordance with any of the embodiments disclosed herein. For example, any suitable ones of the components of the computing device 2800 may include a die (e.g., the die 2502 (FIG. 21)) including one or more IC structures with backend transistors fabricated using seeded epitaxial growth techniques in accordance with any of the embodiments disclosed herein. Any of the components of the computing device 2800 may include an IC package 2600 (FIG. 22). Any of the components of the computing device 2800 may include an IC device assembly 2700 (FIG. 23).

A number of components are illustrated in FIG. 24 as included in the computing device 2800, but any one or more of these components may be omitted or duplicated, as suitable for the application. In some embodiments, some or all of the components included in the computing device 2800 may be attached to one or more motherboards. In some embodiments, some or all of these components are fabricated onto a single system-on-a-chip (SoC) die.

Additionally, in various embodiments, the computing device 2800 may not include one or more of the components illustrated in FIG. 24, but the computing device 2800 may include interface circuitry for coupling to the one or more components. For example, the computing device 2800 may not include a display device 2806, but may include display device interface circuitry (e.g., a connector and driver circuitry) to which a display device 2806 may be coupled. In another set of examples, the computing device 2800 may not include an audio input device 2818 or an audio output device 2808 but may include audio input or output device interface circuitry (e.g., connectors and supporting circuitry) to which an audio input device 2818 or audio output device 2808 may be coupled.

The computing device 2800 may include a processing device 2802 (e.g., one or more processing devices). As used herein, the term “processing device” or “processor” may refer to any device or portion of a device that processes electronic data from registers and/or memory to transform that electronic data into other electronic data that may be stored in registers and/or memory. The processing device 2802 may include one or more digital signal processors (DSPs), application-specific ICs (ASICs), central processing units (CPUs), graphics processing units (GPUs), cryptoprocessors (specialized processors that execute cryptographic algorithms within hardware), server processors, or any other suitable processing devices. The computing device 2800 may include a memory 2804, which may itself include one or more memory devices such as volatile memory (e.g., DRAM), nonvolatile memory (e.g., read-only memory (ROM)), flash memory, solid state memory, and/or a hard drive. In some embodiments, the memory 2804 may include memory that shares a die with the processing device 2802. This memory may be used as cache memory and may include embedded hysteretic memory, e.g., one or more IC structures with backend transistors fabricated using seeded epitaxial growth techniques as described herein.

In some embodiments, the computing device 2800 may include a communication chip 2812 (e.g., one or more communication chips). For example, the communication chip 2812 may be configured for managing wireless communications for the transfer of data to and from the computing device 2800. The term “wireless” and its derivatives may be used to describe circuits, devices, systems, methods, techniques, communications channels, etc., that may communicate data through the use of modulated electromagnetic radiation through a nonsolid medium. The term does not imply that the associated devices do not contain any wires, although in some embodiments they might not.

The communication chip 2812 may implement any of a number of wireless standards or protocols, including but not limited to Institute for Electrical and Electronic Engineers (IEEE) standards including Wi-Fi (IEEE 802.11 family), IEEE 802.16 standards (e.g., IEEE 802.16-2005 Amendment), Long-Term Evolution (LTE) project along with any amendments, updates, and/or revisions (e.g., advanced LTE project, ultramobile broadband (UMB) project (also referred to as “3GPP2”), etc.). IEEE 802.16 compatible Broadband Wireless Access (BWA) networks are generally referred to as WiMAX networks, an acronym that stands for Worldwide Interoperability for Microwave Access, which is a certification mark for products that pass conformity and interoperability tests for the IEEE 802.16 standards. The communication chip 2812 may operate in accordance with a Global System for Mobile Communication (GSM), General Packet Radio Service (GPRS), Universal Mobile Telecommunications System (UMTS), High Speed Packet Access (HSPA), Evolved HSPA (E-HSPA), or LTE network. The communication chip 2812 may operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). The communication chip 2812 may operate in accordance with Code Division Multiple Access (CDMA), Time Division Multiple Access (TDMA), Digital Enhanced Cordless Telecommunications (DECT), Evolution-Data Optimized (EV-DO), and derivatives thereof, as well as any other wireless protocols that are designated as 3G, 4G, 5G, and beyond. The communication chip 2812 may operate in accordance with other wireless protocols in other embodiments. The computing device 2800 may include an antenna 2822 to facilitate wireless communications and/or to receive other wireless communications (such as AM or FM radio transmissions).

In some embodiments, the communication chip 2812 may manage wired communications, such as electrical, optical, or any other suitable communication protocols (e.g., the Ethernet). As noted above, the communication chip 2812 may include multiple communication chips. For instance, a first communication chip 2812 may be dedicated to shorter-range wireless communications such as Wi-Fi or Bluetooth, and a second communication chip 2812 may be dedicated to longer-range wireless communications such as global positioning system (GPS), EDGE, GPRS, CDMA, WiMAX, LTE, EV-DO, or others. In some embodiments, a first communication chip 2812 may be dedicated to wireless communications, and a second communication chip 2812 may be dedicated to wired communications.

The computing device 2800 may include battery/power circuitry 2814. The battery/power circuitry 2814 may include one or more energy storage devices (e.g., batteries or capacitors) and/or circuitry for coupling components of the computing device 2800 to an energy source separate from the computing device 2800 (e.g., AC line power).

The computing device 2800 may include a display device 2806 (or corresponding interface circuitry, as discussed above). The display device 2806 may include any visual indicators, such as a heads-up display, a computer monitor, a projector, a touchscreen display, a liquid crystal display (LCD), a light-emitting diode display, or a flat panel display, for example.

The computing device 2800 may include an audio output device 2808 (or corresponding interface circuitry, as discussed above). The audio output device 2808 may include any device that generates an audible indicator, such as speakers, headsets, or earbuds, for example.

The computing device 2800 may include an audio input device 2818 (or corresponding interface circuitry, as discussed above). The audio input device 2818 may include any device that generates a signal representative of a sound, such as microphones, microphone arrays, or digital instruments (e.g., instruments having a musical instrument digital interface (MIDI) output).

The computing device 2800 may include a GPS device 2816 (or corresponding interface circuitry, as discussed above). The GPS device 2816 may be in communication with a satellite-based system and may receive a location of the computing device 2800, as known in the art.

The computing device 2800 may include an other output device 2810 (or corresponding interface circuitry, as discussed above). Examples of the other output device 2810 may include an audio codec, a video codec, a printer, a wired or wireless transmitter for providing information to other devices, or an additional storage device.

The computing device 2800 may include an other input device 2820 (or corresponding interface circuitry, as discussed above). Examples of the other input device 2820 may include an accelerometer, a gyroscope, a compass, an image capture device, a keyboard, a cursor control device such as a mouse, a stylus, a touchpad, a bar code reader, a Quick Response (QR) code reader, any sensor, or a radio frequency identification (RFID) reader.

The computing device 2800 may have any desired form factor, such as a handheld or mobile computing device (e.g., a cell phone, a smart phone, a mobile internet device, a music player, a tablet computer, a laptop computer, a netbook computer, an ultrabook computer, a personal digital assistant (PDA), an ultramobile personal computer, etc.), a desktop computing device, a server or other networked computing component, a printer, a scanner, a monitor, a set-top box, an entertainment control unit, a vehicle control unit, a digital camera, a digital video recorder, or a wearable computing device. In some embodiments, the computing device 2800 may be any other electronic device that processes data.

The following paragraphs provide various examples of the embodiments disclosed herein.

Example 1 provides an IC structure, including an interconnect layer over a device region, where the interconnect layer includes an insulator material and a conductive interconnect in the insulator material; a semiconductor structure (e.g., a seed) over the interconnect layer, where the semiconductor structure includes a first semiconductor material with a first crystal lattice orientation; a second semiconductor material (e.g., the semiconductor material used for the transistor channel regions) over the semiconductor structure, where: the second semiconductor material has a second crystal lattice orientation that is substantially the same as the first crystal lattice orientation, and a portion of the second semiconductor material is a channel region of a transistor.

Example 2 provides the IC structure of example 1, further including a third semiconductor material (e.g., a textured template) between the second semiconductor material and the interconnect layer, where the third semiconductor material has a third crystal lattice orientation that is substantially the same as the first crystal lattice orientation.

Example 3 provides the IC structure of example 2, where: the semiconductor structure is monocrystalline; and the third semiconductor material (e.g., a textured template) is polycrystalline.

Example 4 provides the IC structure of any one of examples 2 and 3, where: the third semiconductor material has a thickness in a range of 10-100 nanometers, where the thickness is a dimension of the third semiconductor material in a plane substantially orthogonal to the interconnect layer.

Example 5 provides the IC structure of any one of examples 2-4, where: the third semiconductor material is in a same plane as the semiconductor structure, where the plane is substantially parallel to the interconnect layer.

Example 6 provides the IC structure of any one of examples 2-4, where: the semiconductor structure is in a first plane that is substantially parallel to the interconnect layer; and the third semiconductor material is in a second plane over the first plane, where the second plane is substantially parallel to the interconnect layer.

Example 7 provides the IC structure of any one of examples 1-6, where: the semiconductor structure includes a continuous monocrystalline layer of the first semiconductor material through the interconnect layer and in contact with a layer in the device region.

Example 8 provides the IC structure of any one of examples 1-6, where: the semiconductor structure includes a monocrystalline layer on the insulator material.

Example 9 provides the IC structure of any one of examples 1-8, where: the semiconductor structure has a width, where the width is a dimension of the semiconductor structure in a plane substantially parallel to the interconnect layer; the semiconductor structure is one of a plurality of semiconductor structures in the plane; the plurality of semiconductor structures has a pitch; and the width is between 10-50% of the pitch.

Example 10 provides the IC structure of any one of examples 1-9, where: the semiconductor structure has a height in a range of 10-100 nanometers, where the height is a dimension of the semiconductor structure in a plane substantially orthogonal to the interconnect layer.

Example 11 provides the IC structure of any one of examples 1-10, where: the IC structure includes fins or nanoribbons of the second semiconductor material; and the transistor includes the channel region in one of the fins or nanoribbons.

Example 12 provides the IC structure of any one of examples 1-11, where the semiconductor structure includes a first semiconductor structure, and where the IC structure further includes a second semiconductor structure, where a distance between the first semiconductor structure and the second semiconductor structure is in a range of 500 nanometers to 300 microns.

Example 13 provides the IC structure of any one of examples 1-12, where the interconnect layer is a first interconnect layer, and where the IC structure further includes a second interconnect layer over the second layer of the semiconductor material.

Example 14 provides an IC structure, including FEOL layer; a BEOL layer over the FEOL layer, where the BEOL layer includes a dielectric layer and a conductive interconnect in the dielectric layer; a plurality of seed structures over the BEOL layer; a layer of semiconductor material over the plurality of seed structures, where the layer of semiconductor material has a substantially same crystal orientation as the plurality of seed structures; and a transistor over the BEOL layer, where the transistor includes a channel region in the layer of semiconductor material.

Example 15 provides the IC structure of example 14, where: an individual seed structure of the plurality of seed structures includes an epitaxial structure in contact with the FEOL layer and extending through the BEOL layer.

Example 16 provides the IC structure of example 14, where: an individual seed structure of the plurality of seed structures is on the dielectric layer and surrounded by the semiconductor material.

Example 17 provides the IC structure of any one of examples 14-16, where the semiconductor material is a first semiconductor material, and where the IC structure further includes a layer of a second semiconductor material between the BEOL layer and the layer of the first semiconductor material, where the second semiconductor material has the substantially same crystal orientation as the plurality of seed structures.

Example 18 provides the IC structure of example 17, where: the layer of the second semiconductor material includes a portion between adjacent seed structures of the plurality of seed structures, where the portion has a first width; an individual seed structure of the plurality of seed structures has a second width; and the second width is 10-50% of the first width.

Example 19 provides the IC structure according to any one of examples 1-18, where the IC structure includes or is a part of a central processing unit.

Example 20 provides the IC structure according to any one of examples 1-19, where the IC structure includes or is a part of a memory device.

Example 21 provides the IC structure according to any one of examples 1-20, where the IC structure includes or is a part of a logic circuit.

Example 22 provides the IC structure according to any one of examples 1-21, where the IC structure includes or is a part of input/output circuitry.

Example 23 provides the IC structure according to any one of examples 1-22, where the IC structure includes or is a part of a field programmable gate array transceiver.

Example 24 provides the IC structure according to any one of examples 1-23, where the IC structure includes or is a part of a field programmable gate array logic.

Example 25 provides the IC structure according to any one of examples 1-24, where the IC structure includes or is a part of a power delivery circuitry.

Example 26 provides an IC package that includes an IC die including an IC structure according to any one of examples 1-18; and a further IC component, coupled to the IC die.

Example 27 provides the IC package according to example 26, where the further IC component includes a package substrate.

Example 28 provides the IC package according to example 26, where the further IC component includes an interposer.

Example 29 provides the IC package according to example 26, where the further IC component includes a further IC die.

Example 30 provides a computing device that includes a carrier substrate and an IC structure coupled to the carrier substrate, where the IC structure is an IC structure according to any one of examples 1-18, or the IC structure is included in the IC package according to any one of claims 26-29.

Example 31 provides the computing device according to example 30, where the computing device is a wearable or handheld computing device.

Example 32 provides the computing device according to examples 30 or 31, where the computing device further includes one or more communication chips.

Example 33 provides the computing device according to any one of examples 30-32, where the computing device further includes an antenna.

Example 34 provides the computing device according to any one of examples 30-33, where the carrier substrate is a motherboard.

Example 35 provides a method of fabricating an IC structure, the method including providing a preliminary IC structure with a device region over a substrate and an interconnect layer over the device region; providing a seed structure over (or through) the interconnect layer, where the seed structure has a first crystal lattice orientation; providing a first layer of a semiconductor material over the interconnect layer, where the first layer of the semiconductor material has a second crystal lattice orientation that is substantially the same as the first crystal lattice orientation; epitaxially growing a second layer of the semiconductor material over the first layer of the semiconductor material; and forming transistors having channel regions in the second layer of the semiconductor material.

Example 36 provides the method of example 35, further including prior to epitaxially growing the second layer of the semiconductor material: providing an insulator material over the first layer of the semiconductor material, and forming openings in the insulator material; where epitaxially growing the second layer of the semiconductor material includes epitaxially growing the second layer of the semiconductor material in the openings.

Example 37 provides the method of example 35, further including patterning the second layer of the semiconductor material into fins.

Example 38 provides the method of any one of examples 35-37, where the semiconductor material is a first semiconductor material, and where the method further includes epitaxially growing alternate layers of the first semiconductor material and a second semiconductor material.

Example 39 provides the method of example 38, further including forming nanoribbon stacks from the alternate layers of the first semiconductor material and the second semiconductor material, where the channel regions of the transistors are in portions of nanoribbons of the nanoribbon stacks.

Example 40 provides the method of any one of examples 35-39, where: providing the seed structure includes forming an opening through the interconnect layer and through the device region, and epitaxially growing the seed structure over the substrate.

Example 41 provides the method of any one of examples 35-39, where: providing the seed structure includes depositing the seed structure over the interconnect layer with a physical vapor deposition process.

Example 42 provides the method of any one of examples 35-41, where: the first layer of the semiconductor material has a thickness in a range of 10 nanometers to 100 nanometers, where the thickness is a dimension of the first layer of the semiconductor material in a plane substantially orthogonal to the interconnect layer.

Example 43 provides a method of fabricating an IC structure, the method including providing a preliminary IC structure with a device region over a substrate and an interconnect layer over the device region; providing a seed structure over (or through) the interconnect layer, where the seed structure has a first crystal lattice orientation; providing a layer of semiconductor material over the interconnect layer, where the first layer of semiconductor material has a second crystal lattice orientation that is substantially the same as the first crystal lattice orientation; and forming transistors having channel regions in the layer of semiconductor material.

Example 44 provides the method of example 43, where forming the transistors includes patterning the layer of semiconductor material into fins; and forming the transistors in the fins.

Example 45 provides the method according to any one of examples 35-44, where the IC structure is an IC structure according to any one of the preceding claims.

The above description of illustrated implementations of the disclosure, including what is described in the Abstract, is not intended to be exhaustive or to limit the disclosure to the precise forms disclosed. While specific implementations of, and examples for, the disclosure are described herein for illustrative purposes, various equivalent modifications are possible within the scope of the disclosure, as those skilled in the relevant art will recognize. These modifications may be made to the disclosure in light of the above detailed description.

1. An integrated circuit (IC) structure, comprising:
an interconnect layer over a device region, wherein the interconnect layer includes an insulator material and a conductive interconnect in the insulator material;
a semiconductor structure over the interconnect layer, wherein the semiconductor structure includes a first semiconductor material with a first crystal lattice orientation; and
a second semiconductor material over the semiconductor structure, wherein:
the second semiconductor material has a second crystal lattice orientation that is substantially same as the first crystal lattice orientation, and a portion of the second semiconductor material is a channel region of a transistor.

2. The IC structure of claim 1, further comprising:
a third semiconductor material between the second semiconductor material and the interconnect layer, wherein the third semiconductor material has a third crystal lattice orientation that is substantially same as the first crystal lattice orientation.

3. The IC structure of claim 2, wherein:
the semiconductor structure is monocrystalline; and
the third semiconductor material is polycrystalline.

4. The IC structure of claim 2, wherein:
the third semiconductor material has a thickness in a range of 10-100 nanometers, wherein the thickness is a dimension of the third semiconductor material in a plane substantially orthogonal to the interconnect layer.

5. The IC structure of claim 2, wherein:
the third semiconductor material is in a single plane as the semiconductor structure, wherein the single plane is substantially parallel to the interconnect layer.

6. The IC structure of claim 2, wherein:
the semiconductor structure is in a first plane that is substantially parallel to the interconnect layer; and
the third semiconductor material is in a second plane over the first plane, wherein the second plane is substantially parallel to the interconnect layer.

7. The IC structure of claim 1, wherein:
the semiconductor structure includes a continuous monocrystalline layer of the first semiconductor material through the interconnect layer and in contact with a layer in the device region.

8. The IC structure of claim 1, wherein:
the semiconductor structure includes a monocrystalline layer on the insulator material.

9. The IC structure of claim 1, wherein:
the semiconductor structure has a width, wherein the width is a dimension of the semiconductor structure in a plane substantially parallel to the interconnect layer;
the semiconductor structure is one of a plurality of semiconductor structures in the plane;
the plurality of semiconductor structures has a pitch; and
the width is between 10-50% of the pitch.

10. The IC structure of claim 1, wherein:
the semiconductor structure has a height in a range of 10-100 nanometers, wherein the height is a dimension of the semiconductor structure in a plane substantially orthogonal to the interconnect layer.

11. The IC structure of claim 1, wherein:
the IC structure includes fins or nanoribbons of the second semiconductor material; and
the transistor includes the channel region in one of the fins or nanoribbons.

12. The IC structure of claim 1, wherein the semiconductor structure includes a first semiconductor structure, and wherein the IC structure further comprises:
a second semiconductor structure, wherein a distance between the first semiconductor structure and the second semiconductor structure is in a range of 500 nanometers to 300 microns.

13. The IC structure of claim 1, wherein the interconnect layer is a first interconnect layer, and wherein the IC structure further comprises:
a second interconnect layer over the second layer of the semiconductor material.

14. An integrated circuit (IC) structure, comprising:
a front end of line (FEOL) layer;
a back end of line (BEOL) layer over the FEOL layer, wherein the BEOL layer includes a dielectric layer and a conductive interconnect in the dielectric layer;
a seed structure over the BEOL layer;
a layer of semiconductor material over the plurality of seed structures, wherein the layer of semiconductor material has a substantially same crystal orientation as the plurality of seed structures; and
a transistor over the BEOL layer, wherein the transistor includes a channel region in the layer of semiconductor material.

15. The IC structure of claim 14, wherein:
the seed structure includes an epitaxial structure in contact with the FEOL layer and extending through the BEOL layer.

16. The IC structure of claim 14, wherein:
the seed structure is on the dielectric layer and surrounded by the semiconductor material.

17. The IC structure of claim 14, wherein the semiconductor material is a first semiconductor material, and wherein the IC structure further comprises:
a layer of a second semiconductor material between the BEOL layer and the layer of the first semiconductor material, wherein the second semiconductor material has the substantially same crystal orientation as the seed structure.

18. The IC structure of claim 17, wherein:
the seed structure is one of a plurality of seed structures;
the layer of the second semiconductor material includes a portion between adjacent seed structures of the plurality of seed structures, wherein the portion has a first width;
an individual seed structure of the plurality of seed structures has a second width; and
the second width is 10-50% of the first width.

19. A method of fabricating an integrated circuit (IC) structure, the method comprising:
providing a preliminary IC structure with a device region over a substrate and an interconnect layer over the device region;
providing a seed structure over the interconnect layer, wherein the seed structure has a first crystal lattice orientation;
providing a first layer of a semiconductor material over the interconnect layer, wherein the first layer of the semiconductor material has a second crystal lattice orientation that is substantially same as the first crystal lattice orientation;
epitaxially growing a second layer of the semiconductor material over the first layer of the semiconductor material; and
forming transistors having channel regions in the second layer of the semiconductor material.

20. The method of claim 19, further comprising:
prior to epitaxially growing the second layer of the semiconductor material:
providing an insulator material over the first layer of the semiconductor material, and forming openings in the insulator material;
wherein epitaxially growing the second layer of the semiconductor material includes epitaxially growing the second layer of the semiconductor material in the openings.
